(19) United States
(12) Patent Application Publication
(10) Pub. No.: US 2025/0279348 A1
(43) Pub. Date: Sep. 4, 2025

(54) FINISHING ON PACKAGING SUBSTRATE WITH ULTRA HIGH-DENSITY INTERCONNECTS

(71) Applicant: Applied Materials, Inc., Santa Clara, CA (US)

(72) Inventors: Steven Verhaverbeke, San Francisco, CA (US); Han-Wen Chen, Cupertino, CA (US); Giback Park, San Jose, CA (US); Kai Zheng, Santa Clara, CA (US); Kurtis Siegfried Leschkies, San Jose, CA (US); Roman Houk, San Jose, CA (US); Subramanian Srikanteswara Iyer, Los Angeles, CA (US); Vineeth Harish, Midland, GA (US)

(21) Appl. No.: 19/064,570

(22) Filed: Feb. 26, 2025

Related U.S. Application Data
(60) Provisional application No. 63/560,574, filed on Mar. 1, 2024.

(51) Int. Cl. H01L 23/498; H01L 21/48

(52) U.S. Cl. CPC H01L 23/49894; H01L 21/4846; H01L 23/49833

(57) ABSTRACT

A packaging substrate is provided. The packaging substrate includes a core and first organic buildup layers on a first side of the core. The first organic buildup layers include an organic dielectric material and at least one of first metallic traces, first metallic vias, or first metallic pads. The packaging substrate includes second organic buildup layers on a second side of the core that is opposite the first side. The second organic buildup layers include the organic dielectric material and at least one of second metallic traces, second metallic vias, or second metallic pads. The packaging substrate includes first inorganic buildup layers disposed on the first organic buildup layers. The first inorganic buildup layers include an inorganic dielectric material and at least one of third metallic traces, third metallic vias, or third metallic pads.

### CROSS-REFERENCE TO RELATED APPLICATION(S)

The present application claims priority to U.S. Provisional Patent Application No. 63/560,574, filed on Mar. 1, 2024 and entitled “FINISHING ON PACKAGING SUBSTRATE WITH ULTRA HIGH-DENSITY INTERCONNECTS” the entire contents of which are hereby incorporated by reference herein.

### TECHNICAL FIELD

Embodiments of the present disclosure relate, in general, to a method for forming a finishing layer with high-density interconnects onto a packaging substrate. More specifically, the embodiments of present disclosure relate to forming an inorganic dielectric exterior, redistribution layer with high-density interconnects onto an organic dielectric layer of a packaging substrate.

### BACKGROUND

Demand for compact yet powerful electronic technology has catalyzed a shift in the design and fabrication of internal components. One such shift is the miniaturization of integrated circuits (ICs). Smaller ICs mean more components can fit into a given area, leading to enhanced functionality and efficiency within a given technology. Modern, high-density configurations are essential for achieving target levels of performance and efficiency.

Within semiconductor device fabrication, connecting such high-density ICs to further circuity can be helpful. For instance, connecting such an IC to a packaging substrate not only provides a physical base for the IC but also facilitates the electrical connections for the IC to communicate and operate within a larger electronic system. However, as the components and contacts within ICs shrink to microscopic scales, establishing reliable and effective connections to such a packaging substrate becomes increasingly challenging.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In some aspects, a packaging substrate is provided. In some aspects, the packaging substrate includes a core and one or more first organic buildup layers on a first side of the core. The one or more first organic buildup layers include an organic dielectric material and at least one of first metallic traces, first metallic vias, or first metallic pads. The packaging substrate can include one or more second organic buildup layers on a second side of the core that is opposite the first side. The one or more second organic buildup layers include the organic dielectric material and at least one of second metallic traces, second metallic vias, or second metallic pads. The packaging substrate can include one or more first inorganic buildup layers disposed on the one or more first organic buildup layers. The one or more first inorganic buildup layers include an inorganic dielectric material and at least one of third metallic traces, third metallic vias, or third metallic pads.

In some aspects, a method is provided. In some aspects, the method includes depositing a first exterior layer including a first inorganic dielectric material onto a first side of a packaging substrate including a core and one or more interior layers on the first side, the one or more interior layers including a first organic dielectric material and a plurality of conductive traces, removing portions of the first exterior layer to form structures exposing portions of the plurality of conductive traces, depositing conductive material within the structures of the first exterior layer to form a plurality of vias electrically connected to the plurality of conductive traces, depositing a second exterior layer including a second inorganic dielectric material onto the first exterior layer, removing at least a portion of the second exterior layer to form structures exposing portions of the plurality of vias, and depositing conductive material within the structures of the second exterior layer to form a plurality of contact pads configured to electrically connect the packaging substrate to an integrated circuit.

In some aspects, a system is provided. In some aspects, the system includes a packaging substrate, an integrated chip (IC) conductively connected to a first side of the packaging substrate, and a printed circuit board (PCB) conductively connected to a second side of the packaging substrate. In some aspects, the packaging substrate includes a core and one or more first organic buildup layers on a first side of the core. The one or more first organic buildup layers include an organic dielectric material and at least one of first metallic traces, first metallic vias, or first metallic pads. The packaging substrate can include one or more second organic buildup layers on a second side of the core that is opposite the first side. The one or more second organic buildup layers include the organic dielectric material and at least one of second metallic traces, second metallic vias, or second metallic pads. The packaging substrate can include one or more first inorganic buildup layers disposed on the one or more first organic buildup layers. The one or more first inorganic buildup layers include an inorganic dielectric material and at least one of third metallic traces, third metallic vias, or third metallic pads.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1A illustrates a cross-sectional view of an example packaging substrate, according to some embodiments of the present disclosure.

FIG. 1B illustrates a flow diagram of a method to fabricate an example redistribution layer (RDL) of the packaging substrate of FIG. 1A, in accordance with some embodiments of the present disclosure.

FIG. 1C illustrates a flow diagram of a method to fabricate an example transition portion between an interior portion and an exterior portion of the RDL of the packaging substrate of FIG. 1A, in accordance with some embodiments of the present disclosure.

FIG. 1D illustrates a flow diagram of a method to fabricate an example transition portion between an interior portion and an exterior portion of the RDL of the packaging substrate of FIG. 1A, in accordance with some embodiments of the present disclosure.

FIG. 2A illustrates a cross-sectional view of an example redistribution layer (RDL) of the packaging substrate of FIG. 1A, in accordance with some embodiments of the present disclosure.

FIGS. 2B-D illustrate an example exterior portion of a RDL of FIG. 1A at varying stages of the fabrication process, in accordance with some embodiments of the present disclosure.

FIG. 3A illustrates a flow diagram of a method to fabricate an exterior portion of the RDL of FIG. 1A, according to some embodiments of the present disclosure.

FIG. 3B illustrates a flow diagram of a method to fabricate an interior portion of the RDL of the packaging substrate of FIG. 1A, according to some embodiments of the present disclosure.

FIG. 3C illustrates a detailed version of the method of FIG. 3A, according to some embodiments of the present disclosure.

FIG. 4A illustrates an example RDL of the packaging substrate of FIG. 1A at a first stage of fabrication, according to some embodiments of the present disclosure.

FIG. 4B illustrates an example RDL of the packaging substrate of FIG. 1A at a second stage of fabrication, according to some embodiments of the present disclosure.

FIG. 4C illustrates an example RDL of the packaging substrate of FIG. 1A at a third stage of fabrication, according to some embodiments of the present disclosure.

### DETAILED DESCRIPTION

Embodiments are directed to a packaging substrate used to connect an integrated circuit (IC) to a printed circuit board (PCB) or other type of circuit. A packaging substrate can include many vias, pads and electrical interconnects that route pins on an IC (which can be very small and closely spaced) to electrical connections on a PCB (which can be larger and spaced further apart). In embodiments, the packaging substrate includes a redistribution layer (RDL) that has contact pads for connecting to the IC that are even more closely spaced and/or densely positioned than is typically possible for a remainder of the packaging substrate. In embodiments, the packaging substrate includes one or more organic layers on a core (e.g., such as a silicon core), wherein the one or more organic layers act as a first redistribution layer (also referred to herein as a buildup layer). In embodiments, the packaging substrate further includes one or more inorganic buildup layers over the one or more organic layers, wherein the one or more inorganic buildup layers act as a second redistribution layer. The first redistribution layer may connect comparatively widely spaced and large features (e.g., pads, interconnects, vias, etc.) of the core with comparatively narrower and/or smaller features of the of an interior side of the second redistribution layer. The second redistribution layer may connect the features of the first redistribution layer with still narrower and/or smaller features of the IC. The use of the second redistribution layer (e.g., inorganic dielectric buildup layer) may enable more compact arrangement of electrical contacts, vias, etc. for electrically coupling the packaging substrate to ICs.

A redistribution layer (RDL) of a packaging substrate can act as the link between the IC and the packaging substrate in embodiments. The densification and miniaturization of ICs means that the electrical connection points on them are also smaller and more closely spaced. A modern RDL as discussed herein acts as an intermediary layer that provides an expansion of the connection points within an integrated circuit (IC) to a more manageable size for interfacing with the packaging substrate at large. Thus, the RDL addresses this challenge by ‘redistributing’ these tiny connection points across a larger area, effectively translating the micro-scale pattern of the IC to a macro-scale pattern compatible with the packaging substrate. The RDL effectively acts as a bridge, enlarging the tiny connection points of an IC to a scale suitable for interfacing with the substrate. By providing a transition zone, the RDL reduces the risk of physical damage during the manufacturing process and operation, ensuring the long-term reliability and functionality of the semiconductor device.

An RDL can be fabricated layer by layer in embodiments. Each layer can be developed using processes that involve deposition, etching, and patterning techniques.

Deposition (e.g., such as chemical vapor deposition (CVD) or physical vapor deposition (PVD), etc.) can be used for laying down the conductive and/or dielectric layers of an RDL. CVD involves the creation of a solid material from a gaseous precursor, while PVD deposits thin films through physical means, such as sputtering or evaporation.

Etching processes, wet or dry, can further be used to remove unwanted material, creating the RDL structure. Wet etching can use chemical solutions to remove material. Dry etching typically involves reactive gases in a vacuum environment.

Photolithography can play a role in defining the intricate patterns of the layers of an RDL. This often involves coating the packaging substrate with a light-sensitive material, such as photoresist, then exposing it to ultraviolet light through a patterned mask, and developing the image to remove or add either the exposed or unexposed photoresist, depending on the type of resist used.

The fabrication process for an RDL can involve multiple steps, which means repeated rounds of deposition, etching, and patterning. These processes are employed in a cyclical manner to buildup the RDL with multiple layers, each of which can include the same or different materials and/or patterns tailored for specific functions within the device. This iterative process allows for the construction of a complex RDL with precise control over its geometry and material composition.

One type of connection point between and RDL of a packaging substrate and an IC can be a solder bump, which is a small, spherical deposit of solder material on the exterior of the RDL that is used to create a physical and electrical connection between the integrated circuit (IC) and the packaging substrate or another component. These solder bumps can be useful for technologies such as flip-chip packaging, where the IC is mounted upside-down onto the packaging substrate and the connections are made via these bumps. Other types of contact pads can also be formed on or in the packaging substrate.

One parameter of any RDL and the solder bump or contact pad is solder bump/contact pad “pitch.” Solder bump/contact pad pitch refers to the distance between the centers of adjacent solder bumps/contact pads. This measurement, and its minimum, directly impacts the density of connections that can be made on a chip. A smaller solder bump/contact pad pitch means that more connections can fit into a given area, allowing for more compact and densely packed ICs. As the demand for smaller and more powerful electronic devices continues to grow, there is a corresponding goal to pack more transistors and connections into ICs e.g., by enabling both smaller connections and solder bump/contact pad pitch of an RDL.

Reducing bump pitch in a packaging substrate, while simultaneously ensuring robust signal performance introduces several challenges. For instance, a common practice in forming packaging substrates involves roughening the surfaces of copper features or lines, to improve adhesion to materials deposited over them (e.g., such as photoresist or solder mask). While this roughening process enhances adhesion, it can inadvertently compromise performance and signal integrity in transmission lines.

Additionally, when dealing with solder-mask defined copper pads, the bump pitch is constrained by fabrication methods (e.g., current lithography techniques). For instance, with conventional photosensitive solder masks, the bump pitch might be restricted to dimensions of 50 micrometers or more.

Addressing these challenges can be made more difficult by issues such as solder joint fatigue, which arises due to mismatches between the coefficients of thermal expansion (CTEs) between different materials. CTE mismatch between the chip and the substrate, as well as between the substrate and the printed circuit board (PCB), can lead to mechanical stresses and strains on the solder joints. CTE mismatch can compromise the reliability and longevity of the solder joints. Addressing these challenges is a delicate balance between the physical structure of the substrate and the operational demands of modern electronic devices.

Aspects and embodiments of the present disclosure address these and other shortcomings of existing technologies by providing systems and methods for enhancing the performance, integrity, and durability of a RDL of a packaging substrate. Systems and methods disclosed herein decrease the minimum possible solder bump/contact pad pitch, enhancing the performance and signal integrity through transmission lines of a packaging substrate. Additionally, embodiments enable reduced solder ball size as compared to traditional packaging substrates. Additionally, a bumping architecture is provided with copper pillar extension from substrate pad to solder ball pad to enhance the flexibility of interconnect joints for reliability improvement. Furthermore, a dielectric masking material with enhanced adhesion to copper features is proposed, additionally enhancing the mechanical integrity and durability of the packaging substrate.

The proposed systems and methods enable smaller solder bump/contact pad pitch that has previously been obtainable. Smaller solder bump/contact pad pitch allows for more connections per unit area on the chip, facilitating the integration of more functionality into a smaller space. The enabled reduction of bump pitch allows for high-bandwidth electrical connectivity for 3D advanced packaging integration. This improves the quality of chip-to-substrate and substrate-to-PCB interconnects, leading to enhanced chip-and board-level reliabilities, while maintaining economic viability and manufacturability. Smaller solder bump/contact pad pitch also improve performance of a device by reducing the distance electrical signals need to travel, thus increasing speed and reducing power consumption. In embodiments, bump pitch scaling of about 10 micrometers is enabled by proposes systems and methods.

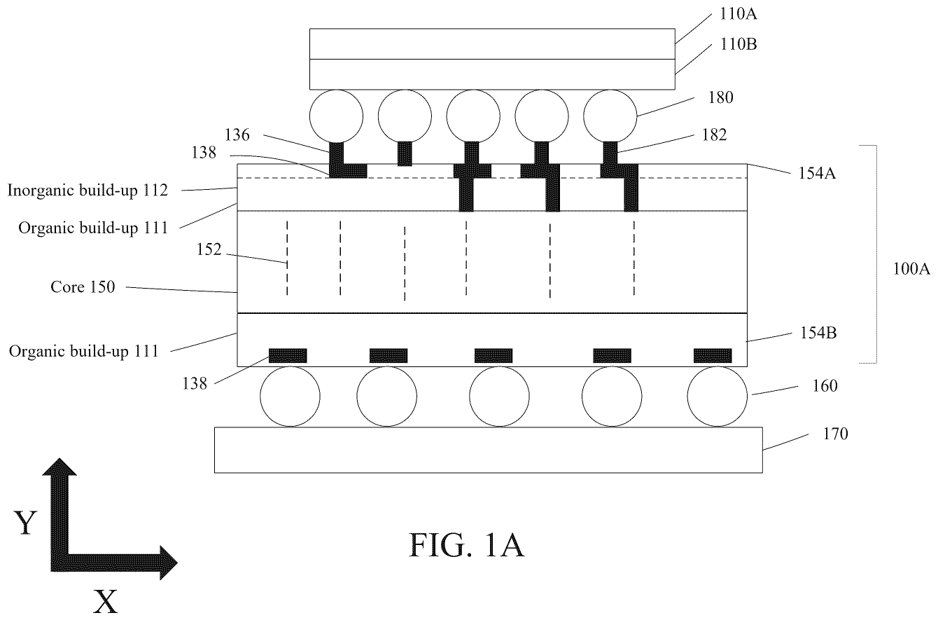

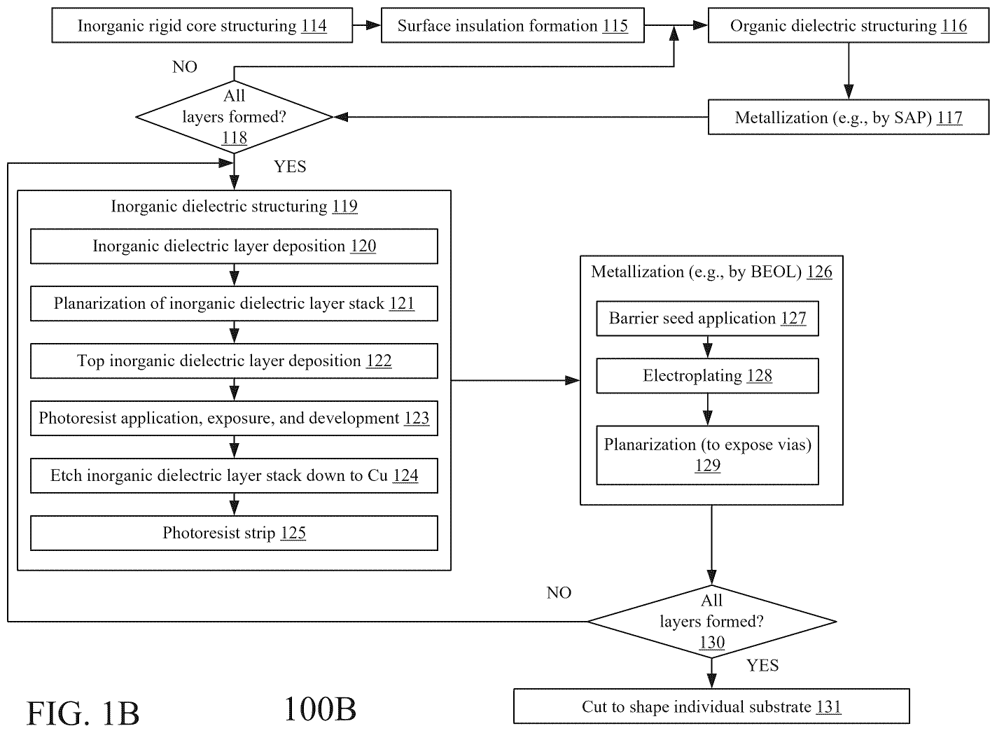

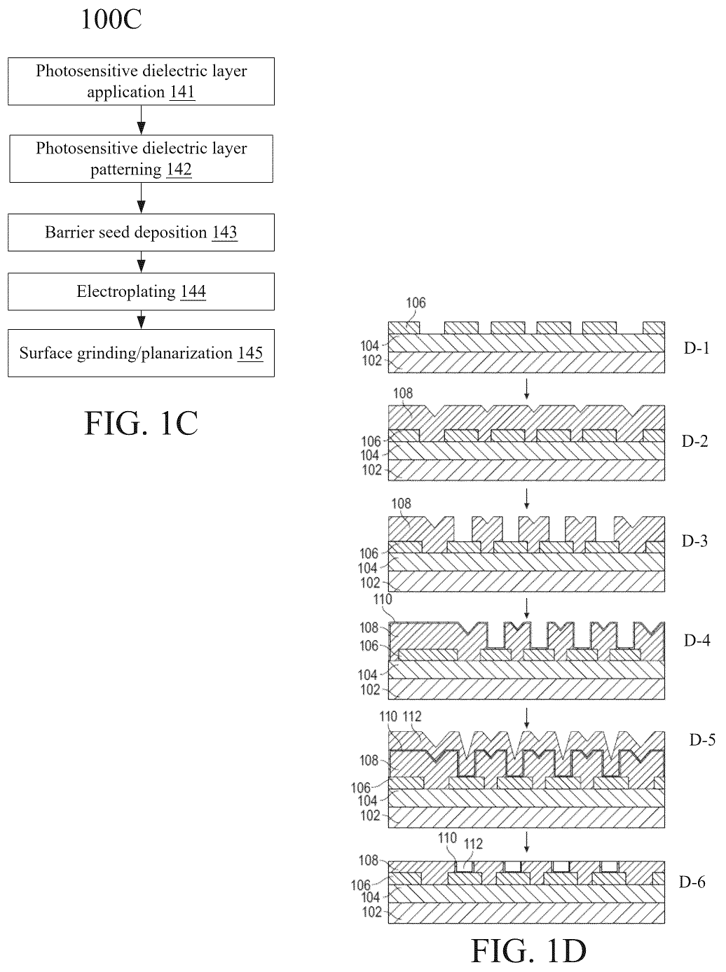

FIG. 1A illustrates a cross-sectional view of an example packaging substrate, in accordance with some embodiments of the present disclosure.

As seen in FIG. 1A, the packaging substrate 100A can be used to electrically connect one or more ICs (e.g., IC 110A and IC 110B) to a PCB 170, through one or more electrical interconnects 136 (e.g., conductive pathways) through the packaging substrate.

The packaging substrate 100A can include a core 150 and top and bottom redistribution layers (RDLs) 154A-B. Core 150 may be a patterned core in embodiments. In embodiments, the core 150 may include a substrate formed from a III-V compound semiconductor material, silicon, crystalline silicon (e.g., Si<100>or Si<111>), silicon oxide, silicon germanium, doped or undoped silicon, doped or undoped polysilicon, silicon nitride, quartz, glass (e.g., borosilicate glass), sapphire, alumina, and/or ceramic materials. In one embodiment, the core 150 includes a monocrystalline p-type or n-type silicon substrate. In one embodiment, the core 150 includes a polycrystalline p-type or n-type silicon substrate. In another embodiment, the core 150 includes a p-type or an-type silicon solar substrate. The substrate utilized to form the core 150 may further have a polygonal or circular shape. For example, the core 150 may include a substantially square silicon substrate having lateral dimensions between about 120 mm and about 180 mm, with or without chamfered edges. In another example, the core 150 may include a circular silicon-containing wafer having a diameter between about 20 mm and about 700 mm, such as between about 100 mm and about 50 mm, for example about 300 mm.

In some embodiments, the core 150 has a thickness T₁ between about 50 μm and about 1000 μm, such as a thickness T₁ between about 70 μm and about 800 μm. For example, the core 150 may have a thickness T₁ between about 80 μm and about 400 μm, such as a thickness T₁ between about 100 μm and about 200 μm. In another example, the core 150 may have a thickness T₁ between about 70 μm and about 150 μm, such as a thickness T₁ between about 100 μm and about 130 μm. In another example, the core 150 nay have a thickness T₁ between about 700 μm and about 800 μm, such as a thickness T₁ between about 725 μm and about 775 μm.

The core 150 may include one or more holes or core vias 152 formed therein to enable conductive electrical interconnections to be routed through the core 150. Generally, the one or more core vias 152 are substantially cylindrical in shape. However, other suitable morphologies for the core vias 152 are also contemplated. The core vias 152 may be formed as singular and isolated core vias 152 through the core 150 or in one or more groupings or arrays, In one embodiment, a minimum pitch Pi between each core via 152 is less than about 1000 μm, such as between about 25 μm and about 200 μm. For example, the pitch Pi may be between about 40 μm and about 150 μm. In one embodiment, the one or more core vias 152 have a diameter V₁ less than about 500 μm, such as a diameter V₁ less than about 250 μm. For example, the core vias 152 may have a diameter V₁ between about 25 μm and about 100 μm, such as a diameter V₁ between about 30 μm and about 60 μm. In one embodiment, the core vias 152 have a diameter V₁ of about 40 μm.

An optional passivating layer (not shown) may be formed on one or more surfaces of the core 150, including a first surface (e.g., top surface), a second surface (e.g., bottom surface), and/or one or more sidewalls of the core vias 152. In one embodiment, the passivating layer is formed on substantially all exterior surfaces of the core 150 such that the passivating layer substantially surrounds the core 150. Thus, the passivating layer may provide a protective outer barrier for the core 150 against corrosion and other forms of damage. In one embodiment, the passivating layer is formed of an oxide film or layer, such as a thermal oxide layer. In some examples, the passivating layer has a thickness between about 100 nm and about 3 μm, such as a thickness between about 200 nm and about 2.5 μm. In one example, the passivating layer 104 has a thickness between about 300 nm and about 2 μm, such as a thickness of about 1.5 μm.

In embodiments, top RDL 154A and/or bottom RDL 154B can be deposited or placed onto the core 150 (e.g., over a passivating layer). RDLs 154A-B can include interior portions (e.g., organic buildup layers 101) and exterior portions (e.g., inorganic buildup layers 103). These interior portions and exterior portions, can themselves be composed of one or more layers (e.g., layer stacks) that are sequentially deposited or placed onto the core.

In some embodiments, the RDLs 154A-B (which will be further described in detail with respect to FIGS. 1B-5) can include multiple electrical interconnects 136 (i.e., conductive pathways) passing through a dielectric material. In embodiments, interconnects 136 can include one or more conductive lines, pads, vias, etc. (e.g., including fine traces). As used herein, “fine traces” can be substantially smaller than “conductive traces.” For example, and in some embodiments, “fine traces” can be between approximately 50 nanometers (nm) and approximately 2 micrometers (μm) in width, while “conductive traces” can be between approximately 2 micrometers (μm) and approximately 50 micrometers (μm) in width. In some embodiments, conductive traces of organic build-up layers can be greater than approximately 2 micrometers (μm) and less than approximately 50 micrometers (μm) in width. In some embodiments, conductive traces of inorganic build-up layers can be greater than approximately 50 nanometers (nm) and less than approximately 2 micrometers (μm) in width. In embodiments, conductive lines can span in the X direction as seen in FIG. 1A, while vias can connect the conductive lines in the Y direction. In embodiments, interconnects 136 can extend through RDLs 154A-B and core 150. In some embodiments, interconnects 136 can extend through the core 150 in what is referred to as a via, or through-core vias (e.g., vias 152).

In embodiments, the packaging substrate 100A and/or RDLs 154A-B can include one or more vias 152 that can include at least one plated through-hole (PTH). A PTH refers to a hole that extends between exterior layers of a packaging substrate (i.e., the top layer of the packaging substrate and the bottom layer of the packaging substrate). A packaging substrate 100A can further include at least one via.

One example of a via structure is a blind via. A blind via refers to a via that connects an exterior layer of a packaging substrate (e.g., the top layer or the bottom layer) to one or more interior layers of the packaging substrate. Accordingly, blind vias are only visible from one side of the packaging substrate. Another example of a via is a buried via. A buried via refers to a via formed between two interior layers of a packaging substrate. Accordingly, a buried via may not be visible from either side of the packaging substrate.

Another example of a via structure that may be used is a through-core via or through-assembly via. One or more through-assembly vias may be formed through one or more of the organic buildup layers and/or through one or more of the inorganic buildup layers. In an example, the through-assembly vias may be centrally formed within the core vias 152 having an insulating layer disposed therein. Accordingly, the insulating layer may form one or more sidewalls of the through-assembly vias, wherein the through-assembly vias may have a diameter V₂ lesser than the diameter V₁ of the core vias 152. In one embodiment, the through-assembly vias have a diameter V₂ less than about 100 μm, such as less than about 75 μm. For example, the through-assembly vias may have a diameter V₂ less than about 50 μm, such as less than about 35 μm. In one embodiment, the through-assembly vias 152 have a diameter of between about 25 μm and about 50 μm, such as a diameter of between about 35 μm and about 40 μm.

The through-assembly vias may provide channels through which one or more electrical interconnections are formed in the packaging substrate 100A. In one embodiment, the electrical interconnections are formed through the entire thickness of the packaging substrate 100A (i.e. from a first major surface to a second major surface of the packaging substrate 100A). For example, the electrical interconnections may have a longitudinal length corresponding to a total thickness of the packaging substrate between about 50 μm and about 1000 μm, such as a longitudinal length between about 200 μm and about 800 μm. In one example, the electrical interconnections have a longitudinal length of between about 400 μm and about 600 μm, such as longitudinal length of about 500 μm. In another embodiment, the electrical interconnections are formed through a portion of the thickness of the packaging substrate 100A (e.g., through the core and through a subset of the RDL layers, such as through the core and through the organic buildup layers). In such embodiment, vias that extend through a subset of the organic and/or inorganic buildup layers and through the cores may be referred to as through-core vias. In further embodiments, the electrical interconnections may protrude from a major surface of the packaging substrate 100A, such as the major surfaces of the packaging substrate 100A. The electrical interconnections may be formed of any conductive materials used in the field of integrated circuits, circuit boards, chip carriers, and the like, For example, the electrical interconnections may be formed of a metallic material, such as copper, aluminum, gold, nickel, silver, palladium, din, or the like.

The resulting structure after formation of the through-assembly vias may be described as a “via-in-via” (e.g., a via centrally formed in a dielectric material within a via of the core structure). The via-in-via structure may include a dielectric sidewall passivation including a ceramic-particle-filled epoxy material and disposed on a thin layer of thermal oxide formed on the sidewalls of the core vias 152 in embodiments.

In embodiments, the packaging substrate 100A can be formed using high density interconnect (HDI) technology. HDI technology can enable a denser packaging substrate design in which more electronics components can be included in a particular area (i.e., reduce the size of a packaging substrate). HDI-based packaging substrates can include at least one plated through-hole (PTH) via or at least one baseband processor (BB) via. HDI-based packaging substrates can further include one or more vias. In some implementations, the one or more vias can include or be referred to as one or more microvias. A microvia can refer to a via hole that has a depth-to-diameter aspect ratio of less than or equal to about 1:1. Due to their size, microvias can be used for high-speed implementations due to a lower parasitic capacitance. Microvias can be formed using any suitable techniques. For example, microvias can be formed by laser drilling via holes, and plating the holes with conductive material (e.g., electroplating).

As mentioned, and as will be further described with respect to FIGS. 1B-5, the exterior layers of a packaging substrate can themselves include one or more portions, or layers, or a stack of layers. For instance, RDL 154A can include one or more inorganic buildup layers 103 at an exterior portion of the RDL 154A and one or more organic buildup layers 101 at an interior portion of the RDL 154A. Layers of the RDL 154A forming the interior and/or exterior portions can be sequentially formed, with electrical interconnects and dielectric materials being included in the layers. Multiple layers can be referred to as buildup layer(s), or a layer stack.

The packaging substrate can further include a core (e.g., core 150) disposed between the pair of RDLs 154A-B. In embodiments, the core 150 can be a monolithic piece. In embodiments, the core 150 is a silicon core, with electrical interconnects formed therein.

In embodiments, vias formed in the core can be of a diameter of about 40 micrometers (μm) (e.g., in the X direction as seen in FIG. 1A). In embodiments, neighboring through-core vias can have a pitch (i.e., a distance between via centers) of about 120 micrometers (μm) (e.g., in the X direction as seen in FIG. 1A).

In embodiments, the packaging substrate 100A can be fabricated using a number of cycles (e.g., lamination cycles), where the number of cycles can depend at least in part on the stack design of the packaging substrate. In embodiments, fabrication can employ cycles to form the RDL including one or more organic buildup layers and/or one or more inorganic buildup layers with a pre-constructed core.

In embodiments, the packaging substrate can conductively connect to one or more ICs (e.g., ICs 111A-B) and/or PCBs (e.g., PCB 170) through connecting portions 180 and 160. In some embodiments, connection portions 160 and/or 180 can be distinct types. E.g., in some cases, portions 180 can be input and output (I/O) bumps while portions 160 can be I/O balls.

In embodiments, such connection portions 160 and/or 180 can interact with contact pads 138 of the packaging substrate.

In embodiments I/O bumps can be, or include, one or more solder points, or copper pillars capped with solder points protruding from an IC (or PCB). In embodiments, such I/O bumps and solder points can be small elements located on the surface of the IC. The bumps can serve as the primary points of electrical contact between the IC and the packaging substrate. When an IC is positioned onto the substrate, the bumps can align with corresponding pads of the substrate.

In some embodiments, I/O balls can be, or include, spheres of solder material attached to an exterior of the packaging substrate. The spheres can serve as a contact point between the packaging substrate 100A and the PCB 170 (or the IC). During assembly, the balls can align with corresponding pads on the PCB 170. In embodiments, a reflow process can be employed to melt the spheres. This melting can create a solid and conductive bond between the substrate and the PCB 170.

In embodiments, the proposed redistribution layers (RDL), can include the top and bottom RDLs 154A-B. RDLs 154A-B may include one or more inorganic buildup layers 103 formed over one or more organic buildup layers 101. The one or more organic buildup layers 101 may form an interior portion of an RDL and may aid in providing electrical connections between the IC and the core 150.

As previously discussed, the RDLs on the packaging substrate including the organic buildup layers and inorganic buildup layers can include reduced bump pitch between neighboring interconnects (e.g., vias, pads, etc.) 136 and/or bump portions 180. In other words, the interconnects 136 of the packaging substrate 100A can be placed closer together, allowing for a smaller form factor, and further miniaturization of the substrate, as compared to traditional packaging substrates. As discussed, this reduction can allow for more electrical connections to an IC per unit area, facilitating the integration of additional functionality, enhancing signal integrity throughout the system, and overall increasing efficiency of the system.

In embodiments, the organic buildup layer(s) 101 can be one or more organic dielectric layers (e.g., Ajinomoto buildup film (ABF)). As discussed, these layers can provide a first transition between pitches of features in the core 150 and pitches of features in ICs. In embodiments, the buildup layer(s) 101 can include metallic portions that protrude from an exterior-most surface of the organic dielectric material of an organic buildup layer.

Inorganic buildup layer(s) 103 of the RDL can include SiO2, Si₃N₄ and/or other inorganic dielectric materials.

A variety of structures and processes can be repeatedly used for fabrication of packaging substrate 100A, as described with respect to FIGS. 1A-4C (e.g., all figures) of the disclosure. As such, a brief description of processes, such a deposition, etching, lithography, planarization, etc. will now be given, that can apply to any and all fabrication processes as described with respect to FIGS. 1A-4C.

In embodiments, a deposition process (e.g., such as a plasma-enhanced or plasma-based deposition process) or method can be used to deposit material onto a surface of a substrate. In an example, dielectric materials (e.g., silicon dioxide or silicon nitride) can be deposited via plasma-enhanced chemical vapor deposition (PECVD). For instance, conductive materials (e.g., copper) can be deposited via physical vapor deposition (PVD). In embodiments, additional types of deposition processes (e.g., plasma spraying, atomic layer deposition (ALD), low-pressure chemical vapor deposition (LPCVD), electron beam physical vapor deposition (EBPVD), etc.) can be used. Other examples of deposition processes include electroplating, anodization, electroless plating, electroless nickel, electroless palladium, and immersion gold (ENEPIG), etc.

In some embodiments, a deposition process can deposit dielectric materials or a dielectric layer onto a surface of a substrate. In embodiments, inorganic dielectric materials may be used to form inorganic buildup layers 103. In embodiments, organic dielectric materials may be used to form organic buildup layers 101. In embodiments, such dielectric materials can include ABF, silicon dioxide (SiO₂), silicon nitride (Si₃N₄), polyimide, etc. For instance, the dielectric material of a dielectric layer can be a polymer, e.g., polyimide. Such a layer can be used as an electrical insulator.

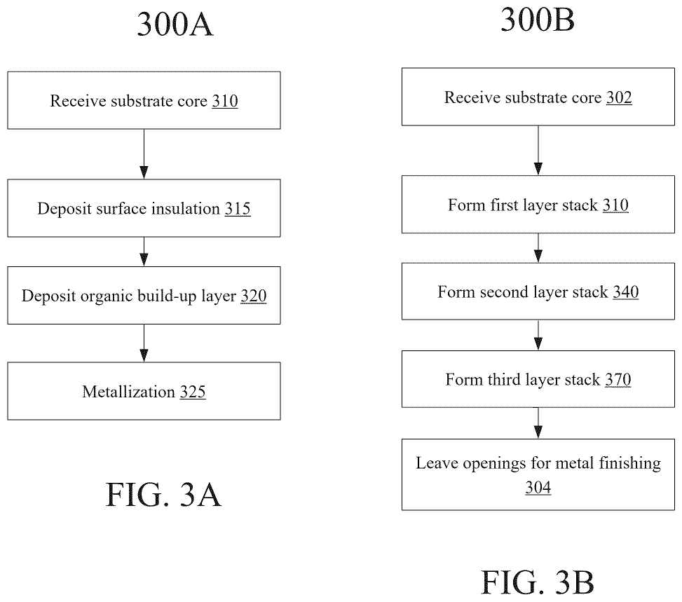

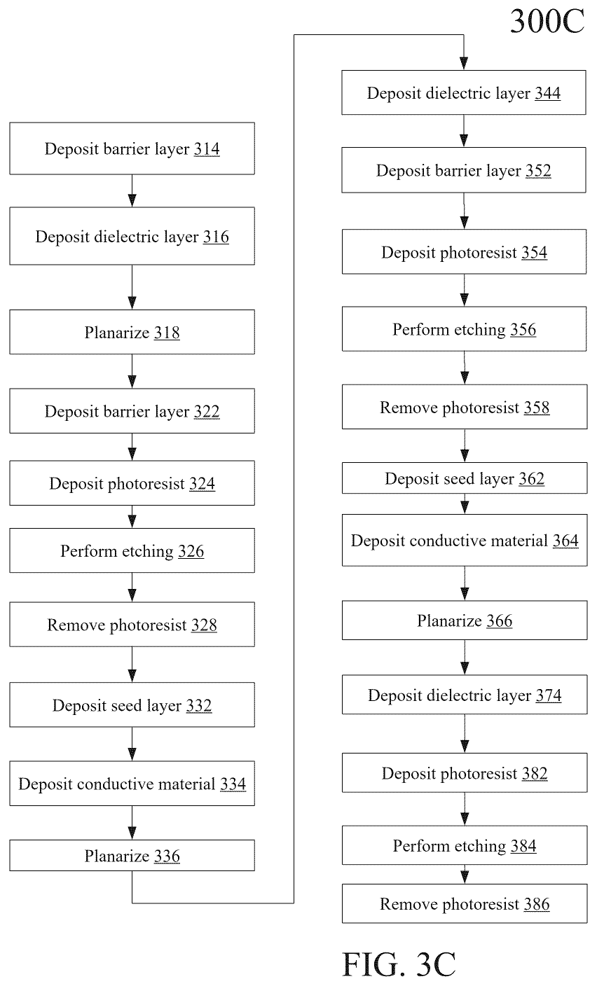

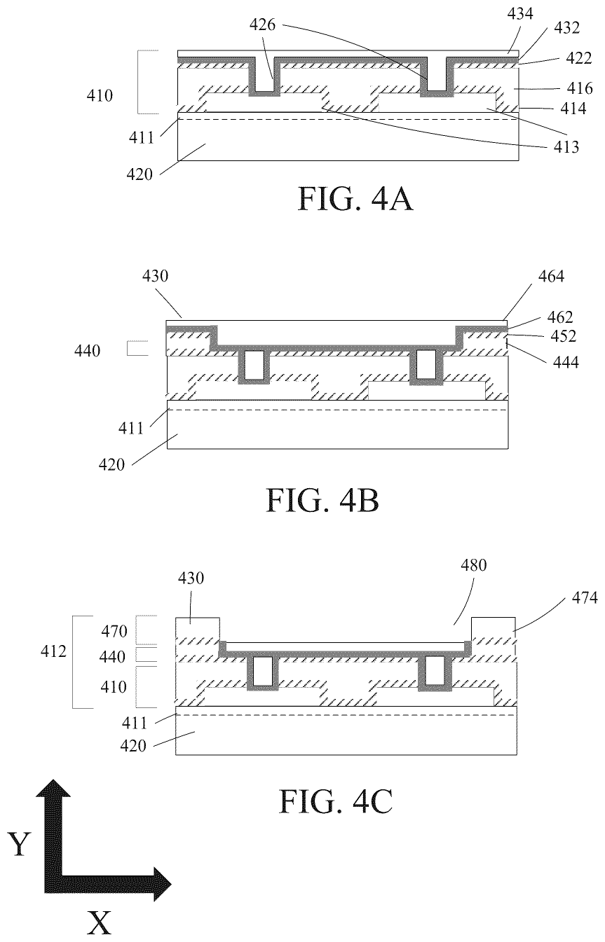

As will be further described below with respect to FIGS. 3A-4C, separate depositions of dielectric layers can be used to form corresponding exterior or interior portions of the RDL. Each layer can include any type or composition of dielectric materials. For instance, in embodiments of a RDL, three layers, or stacks of layers (e.g., layer stacks) 410, 440, 470 of the exterior portion (e.g., portion 412) of the RDL can be formed by dielectric layers separated by barrier layers. In embodiments, the dielectric material of the organic buildup layer(s) 101 can be an organic dielectric such as ABF, and the dielectric material of inorganic buildup layer(s) 103 can be an inorganic dielectric such as silicon dioxide (SiO₂). In embodiments, the dielectric material of inorganic buildup layer(s) can include silicon nitride (Si₃N₄).

In some embodiments, a deposition process can deposit conductive materials that form leads, lines, vias, pads, interconnects, and so on. Deposited conductive materials may be metals, including copper, aluminum, tungsten, molybdenum, etc. Thus, the deposition process can form metallic leads, metallic lines, metallic vias, metallic pads, metallic interconnects and so on. For example, when separated by a non-conductive material, adjacent metallic pads can be formed.

In embodiments, a barrier layer can be applied using a deposition process. Such a barrier layer can be deposited between dielectric layers, conductive layers, etc., for example, and can be used to prevent the diffusion of atoms between different layers. Materials used for a barrier layer can include tantalum, titanium, aluminum, silicon etc., or their nitrides e.g., silicon nitride (Si₃N₄). A barrier layer can be applied when a conductive material such as copper (Cu) or silicon (Si) are used. This can prevent diffusion of the conductive material into the silicon or other materials and layers.

In embodiments, a seed layer can be applied using a deposition process. Such a seed layer can be a thin conductive film that serves as a foundation for subsequent conductive material deposition. Such a seed layer can include copper, nickel, or similar metals. In embodiments, a barrier and seed layer can be deposited simultaneously, as a barrier seed layer.

In embodiments, photoresist material can be applied using a deposition process. Photoresist is a light-sensitive material used in lithographic processes to create a patterned mask on the substrate.

In embodiments, a lithographic process can be used to pattern a deposited photoresist. Such a process can include exposing the photoresist-coated substrate to an actinic light source through a pattern or mask. Such a process can induce a chemical change in the exposed areas of the photoresist. This can create a pattern in the photoresist that corresponds to a target layout. Afterwards, an etching process can be used to remove material or layers as patterned by the photoresist.

In embodiments, an etching process can be performed to etch exposed portions of one or more layers underlying a patterned photoresist. The etching process can be either wet (using chemical solutions) or dry (e.g., using gases or plasmas). Patterned photoresist can serve as a mask for protecting areas of the substrate that should not be etched away.

After the etching process is complete, remaining photoresist can be removed from a substrate surface. Such a stripping process can involve application of a solvent or chemical solution that dissolves the photoresist without damaging the underlying layers or materials.

In such a way, an etching process can be used to form the cavities to be filled with a conductive material for formation of structures such as leads, lines, vias, contact pads, and so on.

In some embodiments, a planarization process can be used to produce a flat and smooth surface on the substrate. In embodiments, a chemical mechanical planarization (CMP) process can be used. In embodiments, any form of chemical etching or polishing in can be used as is feasible and appropriate.

In embodiments, to form a packaging substrate, one or more organic buildup layers are formed. Formation of organic buildup layers may include one or more steps of inorganic dielectric layer formation (e.g., via deposition), patterning, etching, conductive material deposition (e.g., to form leads, vias, contact pads, etc.), chemical mechanical planarization, and so on. In embodiments, organic buildup layers are manufactured using conventional techniques. A top organic buildup layer may include contact pads and/or other electrically conductive features that protrude from the organic buildup layer. Alternatively, the top organic buildup layer may include contact pads and/or other electrically conductive features that are flush (e.g., co-planar) with a surface of the top organic buildup layer.

In embodiments, one or more organic buildup layers include one or more insulating layers (also referred to as dielectric layers) formed on one or more surfaces of the core 150 (or the passivating layer) and may substantially encase the passivating layer and/or the core 150. In embodiments, the insulating layer may extend into the core vias 152 and coat the passivating layer formed on the sidewalls thereof or directly coat the core 150. In one embodiment, the insulating layer has a thickness T₂ from an outer surface of the core 150 or the passivating layer to an adjacent outer surface of the insulating layer that is less than about 50 μm, such as a thickness T₂ less than about 20 μm. For example, the insulating layer 118 has thickness T₂ between about 5 μm and about 10 μm.

In one embodiment, the organic buildup layer(s) are formed of polymer-based dielectric materials. For example, the organic buildup layer(s) may be formed from a flowable buildup material. In a further embodiment, the organic buildup layer(s) may be formed of an epoxy resin material having a ceramic filler, such as silica (SiO₂) particles. Other examples of ceramic fillers that may be utilized include aluminum nitride (AlN), aluminum oxide (Al₂O₃), silicon carbide (SiC), silicon nitride (Si₃N₄, Sr₂Ce₂Ti₅O₁₆, zirconium silicate (ZrSiO₄), wollastonite (CaSiO₃), beryllium oxide (BeO), cerium dioxide (CeO₂), boron nitride (BN), calcium copper titanium oxide (CaCu₃Ti₄O₁₂), magnesium oxide (MgO), titanium dioxide (TiO₂), zinc oxide (ZnO) and the like. In some examples, the ceramic fillers utilized to form the insulating material of the organic buildup layer(s) have particles ranging in size between about 40 nm and about 1.5 μm, such as between about 80 nm and about 1 μm. For example, the ceramic fillers may have particles ranging in size between about 200 nm and about 800 nm, such as between about 300 nm and about 600 nm. In some embodiments, the ceramic fillers include particles having a size less than about 10% of the width or diameter of adjacent core vias 152 in the core 150, such as a size less than about 5% of the width or diameter of the core vias 152.

FIG. 1B illustrates a flow diagram of a process to fabricate an example packaging substrate including one or more inorganic buildup layers of a redistribution layer (RDL) over one or more organic buildup layers, in accordance with some embodiments of the present disclosure. Components, processes, and features as seen and described with respect to FIG. 1B can correspond, or be similar, to similar components as seen and described with respect to FIG. 1A. Thus, embodiments discussed with respect to FIG. 1B, can incorporate and augment at least the embodiments described with respect to FIG. 1A.

In embodiments, method 100B can include steps and operations for fabricating a packaging substrate. At operation 114, inorganic rigid core structuring may be performed. Inorganic rigid core structuring may include forming one or more through vias, channels, etc. in an inorganic rigid core. In embodiments, the inorganic rigid core is a silicon core. The one or more through vias, channels, etc. may be formed, for example, via etching, mechanical drilling, laser drilling, and/or other techniques. Inorganic rigid core structuring may further include filling formed through vias, channels, etc. with an electrically conductive material (e.g., a metal such as aluminum, copper, platinum, etc.).

At operation 115, surface insulation formation may be performed. Surface insulation formation may include performing a deposition process to deposit an organic or inorganic dielectric over one or more portions of the inorganic rigid core. The deposition process used to perform surface insulation may be ALD, CVD, PVD, or another deposition process. In some embodiments, operation 115 is omitted. In some embodiments, channels, vias, etc. are formed in the surface insulation.

At operation 116, organic dielectric structuring may be performed. Organic dielectric structuring may include organic dielectric layer deposition, photoresist application, exposure and patterning of the photoresist, development of the photoresist, etching of the organic dielectric layer, and/or photoresist stripping to result in an organic layer having holes, channels, openings, etc. to be filled with a conductive material.

At operation 117, metallization may be performed to add electrically conductive (e.g., metal) leads, vias, contact pads, and so on (e.g., via a semi-additive process (SAP)). The semi-additive process may include a seed layer deposition, which includes deposition of a thin layer of conductive material (e.g., copper, aluminum, etc.). The semi-additive process may further include photoresist application, exposure and patterning of the photoresist layer, electroplating, photoresist stripping, and optionally additional processes such as etching and/or planarization.

At operation 118, a determination may be made as to whether additional organic buildup layers are to be formed. If additional organic buildup layers are to be formed, the method returns to operation 116. If all organic buildup layers on a side of the packaging substrate have been formed, the method proceeds to operation 119.

At operation 119, inorganic-dielectric structuring may be performed to deposit and form features in one or more inorganic buildup layers over one or more already formed organic buildup layers. In embodiments, operation 119 can include suboperations 120-125. Inorganic dielectric structuring includes forming one or more inorganic dielectric layers and forming channels, holes and/or other features within the inorganic dielectric layers.

At suboperation 120, inorganic dielectric layer deposition may be performed. An inorganic dielectric layer may be formed from a ceramic such as SiO₂, Si₃N₄, and so on. An inorganic dielectric layer may be formed via PVD, CVD, atomic layer deposition (ALD), or other deposition techniques.

At suboperation 121, planarization (e.g., CMP) of one or more inorganic dielectric layers (e.g., an inorganic dielectric layer stack) may be performed. Suboperation 121 may be performed, for example, if the dielectric layer (e.g., organic dielectric layer) over which the inorganic dielectric layer was formed includes protruding electrically conductive features such as pillars, contact pads, traces, and so on. The planarization operation may be performed to smooth out the inorganic dielectric layer(s) and to cause the surface of the inorganic dielectric layer(s) to be flush or coplanar with the surface of the electrically conductive features formed in the underlying layer(s).

At suboperation 122, a top inorganic dielectric layer deposition may be performed. In embodiments, this can include depositing an additional inorganic dielectric layer of an inorganic dielectric layer stack via any of the deposition techniques described herein.

At suboperation 123, photoresist application, exposure, and development may be performed. In embodiments this can include application of photoresist, followed by patterning (e.g., via digital lithographic processing techniques) of the photoresist to generate a pattern onto the photoresist.

At suboperation 124, etching of the inorganic dielectric layer stack may be performed. In embodiments, channels, holes, and/or other features are formed in the inorganic dielectric layer stack. In embodiments, formed channels, holes, features, etc. expose electrically conductive features (e.g., pads, vias, leads, traces, etc.) in the underlying organic dielectric buildup layer(s). For example, the etching may be performed to reveal Cu lines formed in the underlying organic dielectric buildup layer. As will be described in further detail with respect to FIG. 3A-4C, such a process can expose conductive portions (e.g., terminal portions) of the embedded conductive material (e.g., Cu lines).

At suboperation 125, stripping of the photoresist (e.g., as deposited at suboperation 123 may be performed. This can remove all photoresist from the surface of the substrate. Once inorganic dielectric structuring is complete, metallization may be performed to form leads, traces, contact pads, vias, etc. in the formed inorganic dielectric buildup layer(s).

At operation 126, metallization may be performed. In some embodiments, back end of line (BEOL) processing is performed to form the metallization. In embodiments, operation 126 can include suboperations 127-129.

At suboperation 127, a barrier and/or seed layer is formed on the patterned inorganic buildup layer(s). The seed layer may be a thin metal (e.g., Cu, Al, etc.) layer in embodiments.

At suboperation 128, a metal deposition process may be performed to form electrically conductive (e.g., metal) leads, lines, contact pads, vias, etc. in holes, channels, features, etc. formed in the inorganic buildup layer(s). In some embodiments, electroplating is performed to form the electrically conductive leads, lines, contact pads, vias, and so on. Alternatively, another deposition process may be performed to form the conductive material (e.g., Cu material).

At suboperation 129, planarization may be performed. The planarization may be performed to remove deposited electrically conductive material that extends above the surface of the inorganic dielectric layer(s) (e.g., that was deposited on top of the inorganic dielectric layer rather than in the openings, channels, etc. formed in the inorganic dielectric layer. The planarization may cause a surface of the electrically conductive features formed in the inorganic dielectric layer to be flush or coplanar with the surface of the inorganic dielectric layer.

At operation 130, a determination can be made as to whether all inorganic dielectric buildup layers have been formed and/or whether all electrically conductive features (e.g., traces, lines, contact pads, vias, etc.) have been formed in the inorganic dielectric buildup layers. If there are additional inorganic dielectric buildup layers and/or electrically conductive features to be formed, the method may return to operation 119 and/or to operation 126. If all inorganic dielectric buildup layers and all electrically conductive features have been formed, then the method may proceed to operation 131.

In some embodiments, one or more of operations 119-129 may be repeated to form a top dielectric layer (e.g., inorganic dielectric layer) having a copper pillar extension between a contact pad and a solder ball pad. Alternatively, one or more of operations 119-129 may be performed for form a top inorganic dielectric layer over an organic dielectric layer in embodiments. Alternatively, operations different from those of operations 119-129 may be performed to form the top dielectric layer having the copper pillar extension.

The operations may be repeated or performed in order to form an outer redistribution layer without removing a copper seed layer in embodiments. In an example, an inorganic dielectric layer may be formed, such as at suboperation 120. Suboperation 121 may be omitted in embodiments, such as if the underlying inorganic or organic dielectric layer is flush with electrically conductive features of that layer. In some embodiments, suboperation 122 may be performed to form a top dielectric layer (e.g., a barrier layer) over the inorganic dielectric layer in some embodiments.

After suboperation 120 and/or 122, suboperation 123 may be performed to form a patterned photoresist having openings corresponding to copper pillar extensions over contact pads of the underlying layer.

A photoresist strip suboperation 125 may then be performed, followed by an electroplating suboperation 128. Alternatively, the electroplating suboperation 128 may be performed without first performing a photoresist strip suboperation 125 and/or without first performing a barrier seed application suboperation 127. If the electroplating suboperation 128 is performed without first performing a photoresist strip operation, then the photoresist stripping operation may be performed after performing the electroplating suboperation 128.

After the electroplating suboperation 128, a copper barrier seed removal operation may be performed, followed by a dielectric masking operation and an etch-back operation of the dielectric masking layer to expose plated copper pillars. Subsequently, a copper barrier seed deposition operation may be performed, followed by a photoresist application and a patterning operation to define a substrate pad. An electroplating operation may be performed for bumping, followed by a photoresist strip operation, a copper barrier seed removal operation, and an electroless nickel/electroless palladium/immersion gold (ENEPIG) finishing operation. The ENEPIG finishing operation includes formation of a nickel layer using electroless plating, formation of a palladium layer over the nickel layer using electroless plating, and formation of a gold layer over the palladium layer via a displacement reaction (where gold ions in a solution replace the palladium atoms on the surface). This sequence of operations may form a bumping architecture with copper pillar extensions from a substrate pad to a solder ball pad to enhance flexibility of interconnect joints for reliability improvement in embodiments. In embodiments, no copper surface roughening is performed prior to dielectric masking layer application, which may preserve signal integrity and reduce signal transmission loss. In embodiments, pump pitch scaling is enabled with a pump pitch of less than 10 microns in embodiments.

At operation 131, cutting and/or milling of the packaging substrate may be performed to shape the packaging substrate. In some embodiments, method 100B is performed on a core that will be diced into multiple individual packaging substrates. Operation 131 may be performed to then divide the core and its deposited layers into a plurality of individual packaging substrates.

As mentioned, in embodiments inorganic dielectric buildup layers may be formed over an organic dielectric buildup layer that includes protruding electrically conductive features, or may be formed over an organic buildup layer that includes electrically conductive features that are flush with a surface of the organic buildup layer.

FIG. 1C illustrates an example flow diagram for a method 100C for processing an organic buildup layer to cause electrically conductive features of the organic buildup layer to be flush with a surface of the organic buildup layer. FIG. 1D shows cross sectional side views of an organic buildup layer corresponding to operations of method 100C. Components, processes, and features as seen and described with respect to FIGS. 1C-D can correspond, or be similar, to similar components as seen and described with respect to FIGS. 1A-B. Thus, embodiments discussed with respect to FIG. 1C-D, can incorporate and augment at least the embodiments described with respect to FIGS. 1A-B.

As shown, illustration D-1 of FIG. 1D shows a packaging substrate including a core 102 (e.g., an Si core), one or more organic buildup layers 104 formed thereon, and one or more electrically conductive features 106 (e.g., electrical interconnects, metal lines, metal portions) protruding above the organic buildup layer(s) 104. The inorganic buildup layers 104 and core 102 may additionally include electrically conductive features (e.g., electrical interconnects) formed therein, which are not shown for clarity.

At operation 141 of method 100C, a photosensitive dielectric layer may be applied over a surface of the packaging substrate. In embodiments, a photosensitive dielectric layer can be an organic dielectric material. Illustrations D-2 of FIG. 1D. Illustration D-2 shows the photosensitive dielectric layer 108 formed over the organic dielectric layer 104 and over the protruding electrically conductive features 106.

At operation 142, patterning of the photosensitive dielectric layer may be performed. Patterning of the photosensitive dielectric layer may include exposing portions of the photosensitive dielectric layer to light (e.g., UV light) to cure or otherwise chemically alter the exposed portions. Either exposed or non-exposed portions of the photosensitive dielectric layer may then be removed (e.g., via an etch process). Operation 142 can be further seen at illustration D-3 of FIG. 1D. Illustration D-3 can show cavities, channels, etc. formed in the photosensitive dielectric layer 108.

At operation 143, a barrier seed layer may be formed. The barrier seed layer may include a thin metal layer, such as a thin copper layer. Operation 143 can be further seen at illustration D-4 of FIG. 1D. Illustration D-4 can show the barrier seed layer 110 formed over the organic photosensitive dielectric layer 108 and exposed portions of electrically conductive features 106.

At operation 144, an electroplating process or other metal deposition process may be performed to form an electrically conductive layer that fills the cavities, channels, etc. formed in the photosensitive organic dielectric layer 108. In embodiments, conductive materials (e.g., copper) can be deposited onto the dielectric layer 108. Operation 144 can be further seen at illustration D-5 of FIG. 1D. Illustration D-5 can show the conductive layer 112 or material, which has been deposited onto the seed layer 110.

At operation 145, planarization such as surface grinding or CMP may be performed. During planarization, the top layer of the stack can be leveled or planarized. Operation 145 can be further seen at illustration D-6 of FIG. 1D. Illustration D-6 can show the planarized or surface grinded layer stack, including core 102, organic dielectric layer 104, conductive portions 106, dielectric layer 108, barrier seed layer 110, and conductive layer 112.

In embodiments, method 100C can be selectively employed. In other words, in embodiments, the transition portion as described with respect to FIGS. 1C-D can be forgone. Accordingly, in some embodiments, the exterior portion of the RDL (e.g., the inorganic buildup) can be deposited directly onto the interior portion (e.g., as seen in illustration D-1 of FIG. 1D). Alternatively, the exterior portion of the RDL (e.g., the inorganic buildup layers) can be deposited onto the transition portion as (e.g., as seen in illustration D-6 of FIG. 1D).

In embodiments, the transition portion as described with respect to FIGS. 1C-D can be used to generate a level surface prior to deposition of the exterior portion (e.g., inorganic buildup layers). Such a level surface can enhance adhesion, as well as simplify processing methods (e.g., by reducing planarization to be performed during inorganic buildup layer formation).

In embodiments, the transition portion may be formed, or be a part of the interior portion of the RDL, and include similar materials and processing methods. In embodiments, the photo sensitive dielectric material as described within FIGS. 1C-D may include any of the dielectric materials as discussed with respect to the interior portion of the RDL.

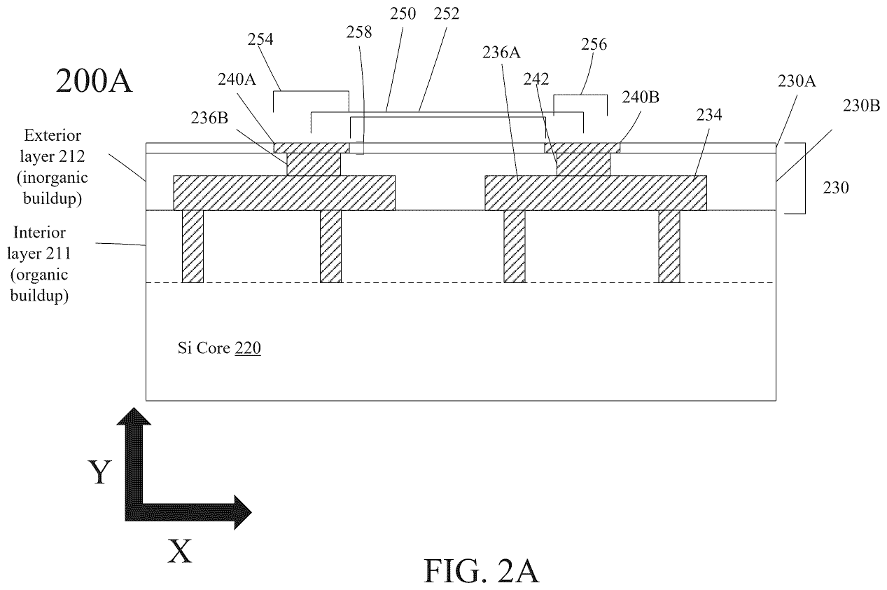

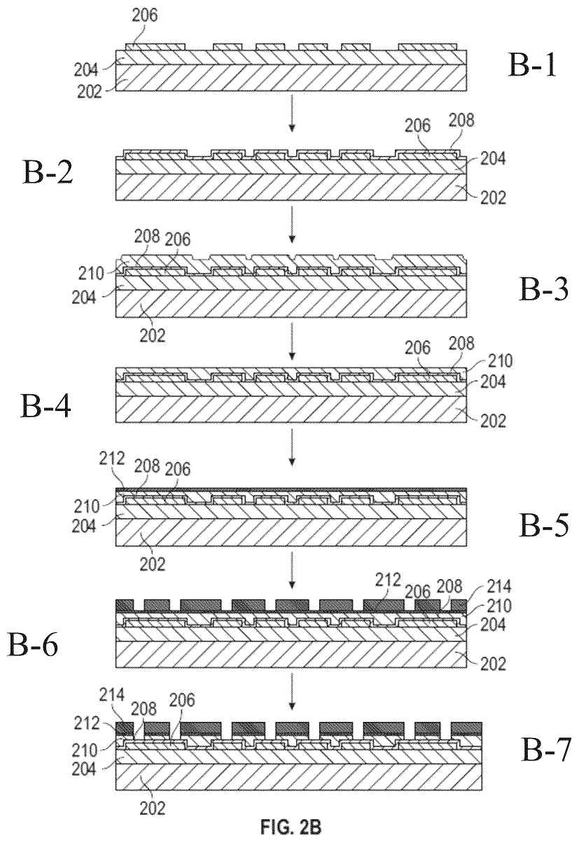

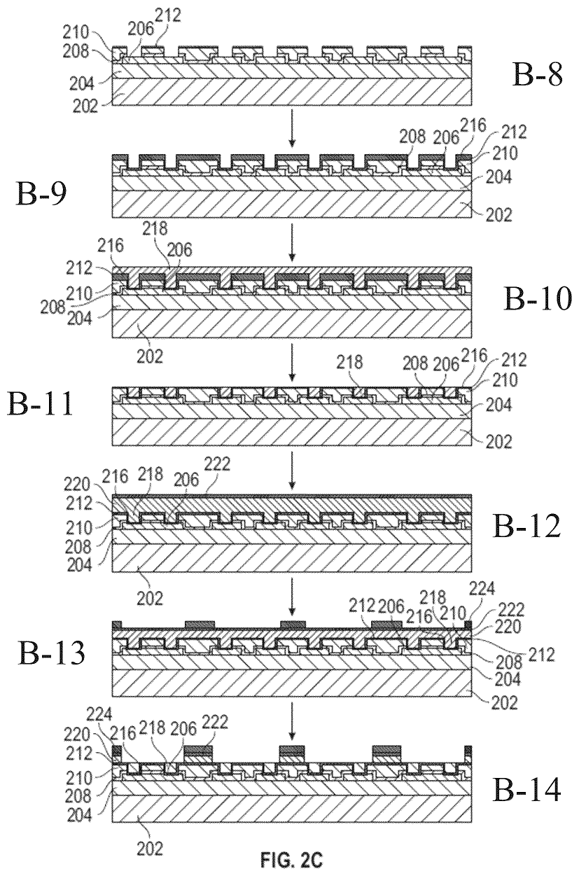

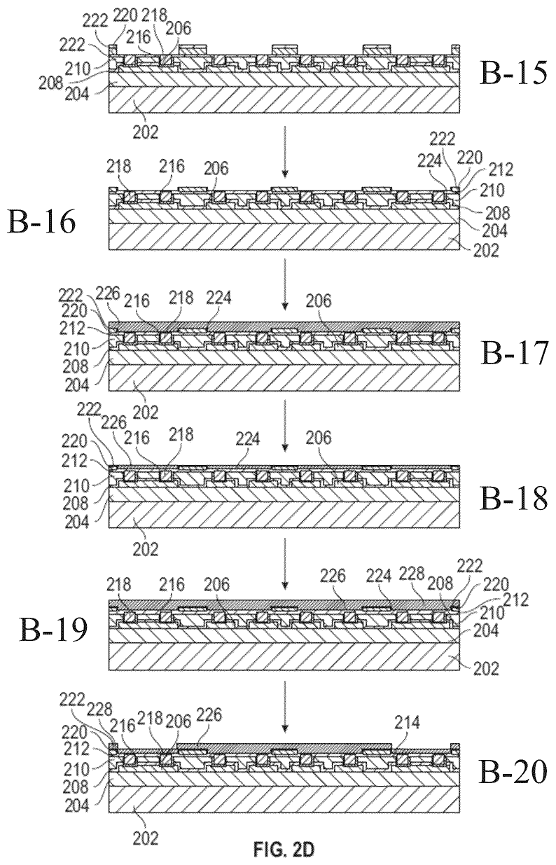

FIG. 2A illustrates a cross-sectional view of an example redistribution layer (RDL) of the packaging substrate of FIG. 1A, in accordance with some embodiments of the present disclosure. Components and features as seen and described in FIG. 2A can correspond, or be similar to components as seen and described with respect to FIG. 1A-D. Thus, embodiments discussed with respect to FIG. 2A can incorporate and augment at least the embodiments described with respect to FIG. 1A-D.

As seen in FIG. 2A, a packaging substrate 200A can include a RDL 230 with an exterior portion 213 (e.g., an inorganic buildup layer) and an interior portion 211 (e.g., an organic buildup layer) placed on a core 201. A corresponding bottom RDL (not shown) can be deposited or placed on a bottom, or second, surface of core 201. In embodiments, the interior portion 211 of the RDL 230 can increase adhesion between RDL 230 and core 201. The interior portion 211 and exterior portion 213 of the RDL 230 can be structured differently and contain varying materials.

In embodiments, the RDL 230 can serve to redistribute fine-pitch connections from an electrical device (e.g., an IC; not shown in FIG. 2A) to a manageable pattern that aligns with the larger-scale of the packaging substrate and any further attached substrate or components (e.g., a PCB).

In some embodiments, the RDL 230 can include multiple electrical interconnects 236A through electrical interconnects 236B (i.e., conductive pathways, as were described with respect to FIG. 1A-D) passing through a dielectric material. In embodiments, interconnects 236A through 236B can extend through RDL 230, core 201, and/or any further layers of the packaging substrate 200A (such as a bottom RDL; not shown in FIG. 2A).

In embodiments, the core (e.g., an Si Core) 220 can provide mechanical support and stability. In embodiments, core 201 can be constructed from materials that offer both rigidity and thermal stability, ensuring the substrate can withstand the thermal and mechanical stresses encountered during both the manufacturing process and operational use. For example, in embodiments, core 201 can be formed from silicon, or an oxidized silicon (i.e., Silica), or any other similar polymer or ceramic material. In some embodiments, the core can be formed from a composite plasticized phenol resin and paper material (e.g., FR-2), a composite material of woven fiberglass (e.g., FR-4), plastics, flexible plastics (e.g., for flexible circuit boards), and so on. In embodiments, the core can be about 110 micrometers (μm) in thickness (e.g., in the Y direction as seen in FIG. 2A).

In embodiments, the dielectric layers interspersed between the conductive pathways can provide electrical insulation and support for the traces. In embodiments, the exterior portion 213 of the RDL 230 can be further divided into an upper layer 230A and a lower layer 230B, which can be of the same and/or different thickness and/or dielectric materials. In embodiments, the upper layer 230A and lower layer 230B can be referred to as a layer stack. In embodiments, the dielectric material of layers of the interior portion 211 and exterior portion 213 can be referred to as a soldering mask. The dielectric material can prevent short circuits between the layers of conductive material (e.g., traces, leads, vias, contact pads, etc.). In embodiments the dielectric material of these portions can be made from materials such as polyimide, silicon dioxide, Ajinomoto buildup film (ABF) or any other similar materials or combination of such. As will be further discussed, the dielectric material of each layer (e.g., layers 230A-B of exterior portion 213, and/or layers of interior portion 211) can vary from one layer to the next.

In embodiments, one or more of the interconnects 236A-B can be formed from conductive materials, e.g., such as copper (Cu), tungsten (W), cobalt (Co), molybdenum (Mo), ruthenium (Ru), etc. Such conductive interconnects 236A-B can form electrical pathways within the RDL 230. Such interconnects 236A-B can be designed to support current loads while minimizing signal loss and crosstalk.

In embodiments, the dielectric materials of layers within interior portion 211 and exterior portion 213 of the RDL 230 can be different. For instance, in some embodiments, layers of interior portion 211 can include organic dielectric material (e.g., a polymer), while layers of exterior portion 213 can include inorganic dielectric material (e.g., silicon dioxide, silicon nitride, etc.). In embodiments, the RDL 230 can be formed from more than 2 portions, including any number of portions as is feasible (e.g., 3, or 4, or 5 portions, etc.). Each portion can include any combination of dielectric materials and layers.

In embodiments, one or more interconnects 236A-B of the RDL 230 can include contact pads (e.g., pad 240A and pad 240B), and one or more pillars or vias 242. Pillars or vias 242 can conductively connect contact pad 240A and pad 240B to internal conductive portions (e.g., portions 234) of the RDL 230. Portions 234 can pass through interior portion 211 and core 201, to conductively connect to a bottom RDL (not shown in FIG. 2A) of the packaging substrate 200A. As discussed, in embodiments, pads (e.g., pad 240A and pad 240B) can be electrical contact points (e.g., made from a conducive material such as copper) and serve as contact points for electrical connections. In embodiments, packaging substrate 200A can include any number of interconnects (including pads, vias, and/or protruding portions) as is feasible.

In embodiments, the distance between adjacent contact pads of the packaging substrate can be characterized by various dimensions. For instance, bump pitch 250 of FIG. 2 can refer to the distance or space between the center of adjacent pads (e.g., pad 240A and pad 240B). Separation 252 can refer to the distance or space between the edges of adjacent pads (e.g., pad 240A and pad 240B). Pad width 254 can refer to the width or distance a single pad can stretch in the X direction (as seen in FIG. 2A). The width of a via 242, or pillar, or opening in the dielectric layer can be referred to as a mask opening 256. The depth, or thickness of a pad can be referred to as pad thickness 258.

As previously discussed, reducing such dimensions can prove advantageous. As such, such dimensions can be sought to be reduced via the manufacturing methods and materials disclosed in embodiments herein (as will be further described with respect to FIGS. 3A-4C).

In embodiments, the proposed methods and materials can be capable of producing or fabricating a packaging substrate with a bump pitch, solder mask opening pitch, and/or contact pad pitch of between 5 and 130 μm. In embodiments, the proposed methods and materials can be capable of producing or fabricating a packaging substrate with a bump pitch, solder mask opening pitch, and/or contact pad pitch that is reduced to a minimum of 5, 10, 15, 20, 25, 30, 40, 50, 75, 90, 100, 120, or 130 μm. Pitch may refer to the distance between centers of adjacent contact pads, solder mask openings, etc.

In embodiments, the proposed methods and materials can be capable of producing or fabricating a packaging substrate with a separation distance between solder mask openings and/or between contact pads of between 5 and 30 μm. In embodiments, the proposed methods and materials can be capable of producing or fabricating a packaging substrate with a separation distance between solder mask openings and/or between contact pads of that is reduced to a minimum of 5, 10, 15, 20, 25, or 30 μm.

In embodiments, the proposed methods and materials can be capable of producing or fabricating a packaging substrate with a pad size between 10 and 30 μm. In embodiments, the proposed methods and materials can be capable of producing or fabricating a packaging substrate with a pad size that is reduced to a minimum of 10, 15, 20, 25, or 30 μm.

In embodiments, the proposed methods and materials can be capable of producing or fabricating a packaging substrate with a mask opening between 2 and 80 μm. In embodiments, the proposed methods and materials can be capable of producing or fabricating a packaging substrate with a mask opening that is reduced to a minimum of 2, 5, 10, 15, 20, 25, 30, 40, 50, or 75 μm.

FIGS. 2B-D illustrate an example exterior portion of a RDL of FIG. 1A at varying stages of the fabrication process, in accordance with some embodiments of the present disclosure. Components, processes, and features as seen and described with respect to FIGS. 2B-D can correspond, or be similar, to similar components as seen and described with respect to FIGS. 1A-2A. Thus, embodiments discussed with respect to FIGS. 2B-D, can incorporate and augment at least the embodiments described with respect to FIGS. 1A-2A.

Illustration B-1 shows a core 202, and an organic dielectric buildup layer (e.g., as seen and described with respect to FIG. 1A) 204 having protruding portion 206, which can be conductive lines, leads, vias, etc. In embodiments, portion 206 can be electrical interconnects extending through the core of the packaging substrate. In some embodiments, illustration B-1 shows a packaging substate after completion of operation 118 of method 100B.

Illustration B-2 shows a barrier seed layer 208 deposited onto the layers shown in illustration B-1. In embodiments, illustration B-2 can correspond to a layer stack after operation 314 of FIG. 3C (as will be described in further detail with respect to FIG. 3C). In embodiments, the barrier seed layer is a thin layer (e.g., 200-900 nm thick, 400 nm thick, 500 nm thick, 600 nm thick, etc.) of an inorganic dielectric material such as Si₃N₄.

Illustration B-3 shows a dielectric layer 210 deposited onto the layers shown in illustration B-2. In embodiments, illustration B-3 can correspond to a layer stack after operation 316 of FIG. 3C (as will be described in further detail with respect to FIG. 3C). In embodiments, the dielectric layer 210 is an inorganic dielectric layer having a thickness of about 1-5 microns (e.g., 2.5-3 microns). In embodiments, dielectric layer 210 comprises or consist of SiO₂. Formation of the dielectric seed layer 208 and the inorganic dielectric layer 210 may be performed at suboperation 120 of method 100B in embodiments.

After formation of the dielectric layer 210, planarization may be performed, corresponding to suboperation 121 of method 100B. Illustration B-4 shows a planarized dielectric layer 210. In embodiments, illustration B-4 can correspond to a layer stack after operation 318 of FIG. 3C (as will be described in further detail with respect to FIG. 3C).

After planarization, an inorganic barrier layer (e.g., of Si₃N₄), also referred to as a top inorganic dielectric layer. may be deposited over the inorganic dielectric layer, as set forth in suboperation 122 of method 100B. The inorganic barrier layer may be relatively thin (e.g., have a thickness of about 100-500 nm, or about 200-300 nm, or about 250 nm in embodiments). Illustration B-5 shows an inorganic barrier layer 212 deposited onto the layers shown in illustration B-4. In embodiments, illustration B-5 can correspond to a layer stack after operation 322 of FIG. 3C (as will be described in further detail with respect to FIG. 3C).

After formation of the barrier layer 212, a photoresist layer may be formed over the barrier dielectric layer (also referred to as a top dielectric layer), and may be patterned, as set forth in suboperation 123 of method 100B. Illustration B-6 shows a photoresist layer 214 deposited and patterned (e.g., via a lithographic process) onto the layers shown in illustration B-5. In embodiments, illustration B-6 can correspond to a layer stack after operation 324 of FIG. 3C (as will be described in further detail with respect to FIG. 3C).

An etch operation may be performed to form openings, channels, etc. in the inorganic dielectric layer 210 and top inorganic dielectric layer 212. The etch operation may be performed in accordance with suboperation 124 of method 100B. Illustration B-7 shows the photoresist layer 214 and other layers as shown in illustration B-6 after an etching process to expose cavities within a top surface of the layer stack of illustration B-6. In embodiments, illustration B-7 can correspond to a layer stack after operation 326 of FIG. 3C (as will be described in further detail with respect to FIG. 3C).

After the etch operation is complete, a photoresist strip operation may be performed, as set forth in suboperation 125 of method 100B. Illustration B-8 shows the layer stack (e.g., the layers) of illustration B-7 after a photoresist stripping process (e.g., after the photo resist layer 214 of illustration B-7 has been removed). In embodiments, illustration B-8 can correspond to a layer stack after operation 328 of FIG. 3C (as will be described in further detail with respect to FIG. 3C).

After the photoresist has been stripped from the inorganic dielectric buildup layer, one or more operations may be performed for metallization of the inorganic dielectric buildup layer, as set forth in operation 126 of method 100B).

A first operation for the metallization process may include forming a barrier seed layer of an electrically conductive material (e.g., of a metal such as Cu). Formation of the barrier seed layer may be performed as set forth in suboperation 127 of method 100B. Illustration B-9 shows a barrier seed layer 216 deposited onto the layers shown in illustration B-8. In embodiments, illustration B-9 can correspond to a layer stack after operation 332 of FIG. 3C (as will be described in further detail with respect to FIG. 3C).

After formation of the barrier seed layer 216, a deposition process such as electroplating may be performed to form an electrically conductive (e.g., metal) layer that fills openings in the inorganic dielectric layer, as set forth in suboperation 128 of method 100B. Illustration B-10 shows a conductive layer 218 deposited onto the layers shown in illustration B-9. In embodiments, illustration B-10 can correspond to a layer stack after operation 334 of FIG. 3C (as will be described in further detail with respect to FIG. 3C).

After formation of the electrically conductive layer, a planarization process may be performed, in accordance with suboperation 129 of method 100B. Illustration B-11 shows the layer stack of illustration B-10 after a planarization process has been applied to the layer stack (e.g., the layers) shown in illustration B-10. The layer stack of illustration B-10 includes one inorganic diel electric buildup layer having multiple vias formed therein. Further operations may be performed to form one or more additional inorganic buildup layers over the already formed inorganic buildup layer. In embodiments, illustration B-11 can correspond to a layer stack after operation 336 of FIG. 3C (as will be described in further detail with respect to FIG. 3C).

Illustrations B-12 to B-18 show various stages of formation of a second inorganic dielectric buildup layer over a first inorganic dielectric buildup layer. These operations may be performed by repeating one or more of operations 119-129 of method 100B of FIG. 1B in an embodiment.

Illustration B-12 can illustrate a dielectric layer (e.g., core 201) and a barrier seed layer 222 deposited onto the layers shown in illustration B-11 after suboperation 120 and 122 of method 100B is performed. Suboperation 121 of method 100B may be omitted since the surface over which the inorganic dielectric layer (e.g., core 201) has been deposited was already flat. In embodiments, illustration B-12 can correspond to a layer stack after operation 344 of FIG. 3C (as will be described in further detail with respect to FIG. 3C).

Illustration B-13 shows a photoresist layer 224 deposited and patterned (e.g., via a lithographic process) onto the layers shown in illustration B-12 after suboperation 123 of method 100B has been performed. In embodiments, illustration B-13 can correspond to a layer stack after operation 354 of FIG. 3C (as will be described in further detail with respect to FIG. 3C).

Illustration B-14 shows the photoresist layer 224 and other layers as shown in illustration B-13 after an etching process to expose cavities within a top surface of the layer stack of illustration B-13 after suboperation 124 of method 100B has been performed. In embodiments, illustration B-14 can correspond to a layer stack after operation 356 of FIG. 3C (as will be described in further detail with respect to FIG. 3C).

Illustration B-15 shows the layer stack (e.g., the layers) of illustration B-14 after a photoresist stripping process (e.g., after the photo resist layer 224 of illustration B-14 has been removed) has been performed in accordance with suboperation 125 of method 100B. In embodiments, illustration B-15 can correspond to a layer stack after operation 358 of FIG. 3C (as will be described in further detail with respect to FIG. 3C).

Illustration B-16 shows a barrier seed layer 224 deposited onto the layers shown in illustration B-15 after suboperation 127 of method 100B has been performed. In embodiments, illustration B-16 can correspond to a layer stack after operation 362 of FIG. 3C (as will be described in further detail with respect to FIG. 3C).

Illustration B-17 shows a conductive layer 226 deposited onto the layers shown in illustration B-16 after suboperation 128 of method 100B has been performed. In embodiments, illustration B-17 can correspond to a layer stack after operation 364 of FIG. 3C (as will be described in further detail with respect to FIG. 3C).

Illustration B-18 shows the layer stack of illustration B-17 after a planarization process has been applied to the layer stack (e.g., the layers) shown in illustration B-17, in accordance with suboperation 129 of method 100B. In embodiments, illustration B-18 can correspond to a layer stack after operation 366 of FIG. 3C (as will be described in further detail with respect to FIG. 3C).

Illustrations B-19 to B-20 show various stages of formation of a third inorganic dielectric buildup layer over a second inorganic dielectric buildup layer. These operations may be performed by repeating one or more of operations 119-129 of method 100B of FIG. 1B in an embodiment. In embodiments, the third inorganic dielectric buildup layer does not include any electrically y conductive features formed therein. In some embodiments, the third inorganic dielectric buildup layer can include fourth metallic traces, fourth metallic vias, or fourth metallic pads.

Illustration B-19 shows an inorganic dielectric layer 228 (e.g., SiO₂) deposited onto the layers shown in illustration B-18 after performance of suboperation 120 of method 100B. In embodiments, illustration B-19 can correspond to layer stack after operation 374 of FIG. 3C (as will be described in further detail with respect to FIG. 3C).

Illustration B-20 shows a dielectric layer 228 after a photoresist deposition and patterning operation, after an etching process, and after a photoresist stripping process to expose electrically conductive features such as contact pads of the second inorganic dielectric layer. In embodiments, illustration B-20 can correspond to a layer stack after operations 368, 372, and/or 374 of FIG. 3C (as will be described in further detail with respect to FIG. 3C). In some embodiments, metal finishing operations may be performed after exposing the electrically conductive features.

FIG. 3A illustrates a flow diagram of a method to fabricate an interior portion of the RDL of the packaging substrate of FIG. 1A, according to some embodiments of the present disclosure. Components, processes, and features as seen and described with respect to FIG. 3A can correspond, or be similar, to similar components as seen and described with respect to FIGS. 1A-2D. Thus, embodiments discussed with respect to FIG. 3A, can incorporate and augment at least the embodiments described with respect to FIGS. 1A-2D.

In embodiments, process 300A can be used to form an interior portion (e.g., organic buildup buildup 101, interior portion 211, interior portion 411, of FIGS. 1A-4C) onto a substrate core. In embodiments, process 300B-C (as will be further described with respect to FIGS. 3B-C) can be used to form an exterior portion of an RDL onto an interior portion formed by process 300A. Thus, in some cases, processes 300B-C can be performed after process 300A. Alternatively, process 300A can be, included, or be a part of, the processes described within FIGS. 3B-C (e.g., processes 300B-C). In embodiments, a transition portion (e.g., as described with respect to FIGS. 1C-D) may be inserted between the interior and exterior portions as described with respect to FIGS. 3A-C.

Operation 302 can begin process 300A by receiving or forming substrate core. As discussed, in embodiments, a substrate core can be a monolithic piece that provide structure support for a packaging substrate. The received substrate core can include contact pads on an exterior surface of the substrate core. These contact pads can be connected to through-core vias. The contact pads can include a copper seed layer on an exterior surface of the contact pads.

At operation 304, surface insulation or a dielectric material, can be deposited onto at least one surface of the substrate core. The surface insulation can be any of the dielectric materials previously discussed. The surface insulation can be ABF material, a non-conductive conductive epoxy, etc. In embodiments, operation 304 can also include lithographic patterning and a descumming process to precisely define the spaces or patterns for conductive interconnects. Operation 304 can also include depositing conductive material onto the patterned insulation.

Operation 306 can include forming one or more (organic) buildup layers onto the insulation layer of operation 304. This can include depositing a dielectric material (e.g., ABF) onto the insulation surface. This can include patterning the dielectric material. This can include the use of photoresist, in embodiments. The dielectric material can be patterned by depositing photoresist. As discussed, a film of photoresist can be deposited onto an exterior surface of the insulation and patterned via a lithographic process. This pattern can act as a mask during following etching or deposition processes (e.g., an electroplating process). After, the photoresist can be removed. This can allow metal to be deposited only in the target areas.

At operation 308, a metallization process, such as copper electroplating, can be performed to selectively deposit conductive copper material into the pattern formed by operation 304. Operation 306 can form a vertically extending conductive portion (e.g., a copper that can terminated in an exposed conductive portion (e.g., such as conductive portion 413 of FIG. 4A).

In embodiments, operations 306 and 308 can be repeated as many times as appropriate to generate repeated buildup layers of the interior portion (e.g., organic buildup) of an RDL.

FIGS. 3B-C, illustrate flow diagrams of methods and subprocesses to fabricate an exterior portion of a RDL of a packaging substrate, and will be discussed together. FIGS. 4A-C illustrate a RDL of a packaging substrate at different stage of fabrication, and will be discussed together, as well as in tandem with FIGS. 3B-C.

In some embodiments, process 300C of FIG. 3C can illustrate a detailed process 300C that is a more detailed version of process 300B of FIG. 3B.

FIGS. 4A can illustrate an example RDL of a packaging substrate at a first stage of fabrication. FIG. 4B can illustrate an example RDL of a packaging substrate at a second stage of fabrication. FIG. 4C can illustrate an example RDL of a packaging substrate at a third stage of fabrication. Although FIGS. 4A-C illustrate a single RDL of a packaging substrate, in embodiments, similar processes (as discussed with respect to FIGS. 3A-C), and formations can be seen on separate exterior layers of the packaging substrate (e.g., a top RDL can be seen in FIG. 4; a bottom RDL can similarly be fabricated to form a packaging substrate).

Components and features as seen and described in FIGS. 3B-C and 4A-C can correspond, or be similar, to similar components as seen and described with respect to FIGS. 1A-3A. Thus, embodiments discussed with respect to FIGS. 3B-C and 4A-C, can incorporate and augment at least the embodiments described with respect to FIGS. 1A-3A.

Although shown in a particular sequence or order, unless otherwise specified, the order of the processes of FIGS. 3B-C can be modified. Thus, the illustrated embodiments should be understood only as examples, and the illustrated processes can be performed in a different order, and some processes can be performed in parallel. Additionally, one or more processes can be omitted in various embodiments. Thus, not all processes are performed in every embodiment. Other process flows are possible.

Processes and methods as described within FIGS. 3B-C can be reused, and include a variety of systems, processes, and methods (e.g., within the processes described within as well as with respect to FIG. 3A).

FIG. 3B illustrates a flow diagram of a method to fabricate an exterior portion of the RDL of FIG. 1A, according to some embodiments of the present disclosure.

As seen at operation 312, process 300B of FIG. 3B can include receiving a substrate core of a packaging substrate. In embodiments, the received substrate core can already include an interior portion (e.g., one or more buildup layers of an RDL, with partially formed conductive pathways) and/or a transition portion of the RDL formed on the core. Thus, process 300B can include forming a first layer stack of the exterior portion of the RDL, at operation 314, forming a second layer stack on the first layer stack, at operation 316, forming a third layer stack on the second layer, at operation 318, and leaving openings for metal finishing at operation 320. Exemplary embodiments of the first, second, and third layer stacks of the exterior portion discussed within FIG. 3B-C can correspond to layer stacks 410, 440, 470, as seen and described with respect to FIGS. 4A-C.

At operation 312, a core of a packaging substrate can be received or obtained. In some embodiments, the packaging substrate is an HDI-based packaging substrate. As discussed with respect to FIGS. 1A-3A), the core can be formed from a first set of layers, or can be a monolithic structure. In embodiments, the first set of layers can be a stack of alternating conductive layers and non-conductive layers. For example, the first set of layers can include a first conductive layer corresponding to a first end of the core and a second conductive layer corresponding to a second end of the core opposite the first end.

In embodiments, the core can be a silicon core. In embodiments, the core can be obtained with one or more buildup layers of an interior portion of the RDL (e.g., portion 411), already formed on the core. In embodiments, operation 312 can include forming the interior portion 411 (e.g., via the process 300A of FIG. 3A). The exterior portion 412, as described within FIGS. 3B-4C can be formed on the surface of the interior portion 411. In other words, interior portion 411 can become intermediate layers of the RDL of the packaging substrate, disposed between the (silicon) core and the exterior portion formed by layer stacks 410, 440 470, of the packaging substrate (as seen in FIG. 4A). In embodiments, interior portion 411 can include one or more dielectric materials or layers. In embodiments, portion 411 can include a dielectric material that is an organic dielectric material, an ABF layer, a GL102 film, etc., deposited onto a surface of the substrate core (e.g., core 420). In embodiments, the interior portion 411 can include protruding conductive portions (e.g., portions 413 of FIG. 4A). In embodiments, the exterior portion of the RDL can be formed on a surface of these features. In embodiments, the core can include one or more vias (e.g., through-core vias) formed within the core. In embodiments the conductive portions (e.g., portions 413 of FIG. 4A) protruding from the core can be conductively connected to these vias.

In some embodiments, obtaining the core includes forming the core, with or without interior portion 411.

At operation 314, a first layer stack of the exterior portion of the RDL can be formed on the interior portion (in embodiments, they can be formed directly onto the core). Such a first layer stack can be seen in FIGS. 4A-C as layer stack 410. Layer stack 410 can include a layer 416 of dielectric material that can include or be any of the dielectric materials previously discussed (e.g., organic, inorganic, conductive, non-conductive, etc.) In embodiments, layer stack 410 can include a dielectric material that is ABF, silicon dioxide (SiO₂), silicon nitride (Si₃N₄), polyimide, etc.

As mentioned above, in embodiments, similar processes can be substituted for the etching process of the first dielectric layer. For instance as will be described below, the traditional etching process (e.g., with the inclusion of photoresist) can continue, including the use of photoresist, photolithography, stripping, etc. However, as mentioned, in some embodiments alternate methods of forming the via structures can be used. For instance, in some embodiments, the dielectric material itself can be photosensitive (and photoresist may not be applied). In embodiments, alternate to an etching process, a drill can be substituted to physically excavate and form a pillar structure, prior to deposition of conductive material. In some embodiments, a laser cutting process can be used to burn, or otherwise material to perform a similar cavity formation, or via structure formation process. In other embodiments, similar or any suitable methods of cavity or via structure formation can be used. As discussed with respect to FIG. 4A, in embodiments, dielectric material of the first exterior layer can be ABF, silicon dioxide (SiO₂), silicon nitride (Si₃N₄), polyimide, etc.

In some embodiments, alternate, or multiple forms of etching can be used. For instance, in some embodiments, lithography can be performed (sans photoresist) to pattern the dielectric layer or material itself. This patterned dielectric layer can then be etched (again, sans photoresist) to form the cavities, or pillar structures, to be further completed with conductive material. In further embodiments, a photoresist can first be deposited over the dielectric layer, the photoresist can be patterned, then the photoresist can be etched. After, the top layer can be etched, and the patterned photoresist can be removed. In such a way, cavities, or structure to form the pillars can be formed.

As discussed, in some embodiments of the disclosure, a laser cutting process can be used to generate pillar structures or cavities at operation 306. For instance, in the case where the dielectric material or layer is non-photosensitive, a laser cutting process (or any other similar process) can be used to generate the via structures or cavities. Such can be the case when the dielectric material targeted for cavity formation is polymer, epoxy, ABF, or any other similar or non-photosensitive material. In embodiments, even when a dielectric material or layer is photosensitive, a laser cutting process (or any other similar process) can still be used to generate the via structures or cavities.

As discussed, in alternate embodiments, if the dielectric material is photosensitive, such a material and layer can be directly etched (again, sans photoresist) after exposure of direct lithography to the layer to pattern the layer. Etching of the patterned, top, dielectric layer, can then be performed to form the cavities, or pillar structures, in the layer. Direct lithography and etching (without using photoresist) can be performed when the dielectric material targeted for cavity formation is a photosensitive organic compound. For example, some light sensitive polymers (e.g., photosensitive polyimides), or any other similar or other photosensitive, dielectric material can be used for the layers in embodiments.

In alternate embodiments, regardless of the photosensitivity of the dielectric material or layer being used, a photoresist layer can first be applied, and patterned via photolithography. For instance, in the cases of a non-photo sensitive dielectric such as silicon dioxide, which is used as a dielectric material and layer, a photoresist layer can first be applied to the outermost surface of the dielectric layer. After, patterning, etching, and stripping can occur to from the via structures or cavities in the non-photo sensitive dielectric material and layer.

In embodiments, depositing a first dielectric layer stack (e.g., layer 416) can include operation 322, depositing a barrier layer (e.g., layer 414) onto the interior layer of the RDL or substrate core and operation 324, depositing the dielectric material (e.g., of layer 416) onto the barrier layer. In embodiments, the dielectric material (e.g., of layer 416) can be an inorganic dielectric. In embodiments, the dielectric material (e.g., of layer 416) can be any of the above-discussed dielectric materials (e.g., SiO₂). After operation 324, operation 326 can include planarizing the dielectric material (e.g., of layer 416).

In embodiments, etching the first dielectric layer can first include operation 328, depositing a barrier layer (e.g., layer 422) onto the dielectric layer (e.g., layer 416). After, operation 332 can include forming a photoresist pattern onto the barrier layer, operation 334 can include performing an etching process to expose the conductive layer (e.g., portions 413), and operation 336 can include removing the photoresist.

As seen in FIGS. 3C and 4A-C, operation 334 can expose the conductive portions 413, by generating pillars 426, or pillar structures, from the top-most surface through barrier layer 422, dielectric layer 416, and/or barrier layer 414. Afterwards, conductive material can be deposited into the structures to create pillars 426. Such deposition of conductive material can form a conductive pathway to conductive portions 413 of the core. As seen in FIG. 4A-C, a conductive material of layer 434 can have been deposited, but not yet planarized.

In embodiments, operation 314 (as seen in FIG. 3B), and/or operations 322 through 344 (as seen in FIG. 3C) can be repeated so as to form more than one inorganic buildup layers of the first layer stack 410. Each layer can include inorganic dielectric materials. In embodiments, these inorganic buildup layers can be formed onto the interior portion 411, which can be organic. For instance, in embodiments, layers of portion 411 can be ABF. In alternate embodiments, layer 416 can be a silicon-based material. In embodiments, operation 314, and/or operations 322 through 344 can be repeated any number of times as is feasible or appropriate.

In embodiments, depositing conductive material of operation 342 can include depositing a seed layer (e.g., layer 432) onto the barrier layer (e.g., layer 422), as seen at operation 338. After, as seen at operation 342, conductive material can be deposited onto the seed layer, and the conductive layer (e.g., layer 434) can be planarized, as seen at operation 344.

In embodiments, planarization of layer 434 (as seen in FIG. 4A) can decrease the conductive material in the Y direction, until the material within the pillars 426 is flush or level with the barrier layer 432.

Returning now to FIG. 3B, at operation 316, a second layer stack of the exterior portion of the packaging substrate can be formed on the first layer stack. Such a second layer stack can be seen in FIGS. 4A-C as second layer stack 440 which can be formed above first layer stack 410.

In embodiments, as seen with respect to FIG. 3C, the second layer stack of operation 316 can be formed by first depositing a dielectric layer, etching the dielectric layer, as seen at operation, and depositing conductive material. These suboperations of operation 316 and the formation of the second layer stack of the exterior portion will now be described in further detail with respect to both FIGS. 3C and 4A-C.

In embodiments, depositing the dielectric layer of operation 316 can include depositing a dielectric layer (e.g., layer 444) onto the first layer as was planarized in operation 344. In embodiments, the dielectric material (e.g., of layer 444) can be an inorganic dielectric material. In embodiments, the dielectric material (e.g., of layer 444) can be any of the above-discussed dielectric materials (e.g., Si₃N₄). Such an operation is seen at operation 346 of FIG. 3C.

In embodiments, etching the second dielectric layer of operation 316, can include depositing a barrier layer (e.g., layer 452) onto the dielectric layer (e.g., layer 444) as seen at operation 348. Afterwards, operation 352 can include depositing a photoresist pattern (not shown with respect to FIGS. 4A-C) onto the barrier layer, performing an etching process to expose the conductive layer, and removing the photoresist (as seen at operations 354 and 356).

In embodiments, depositing the conductive material of operation 316 can include depositing a seed layer (e.g., layer 462) onto the barrier layer (e.g., layer 452) as seen at operation 358. After, conductive materials 430 (e.g., materials of layer 464) can be deposited onto the seed layer, as seen at operation 362, and the conductive layer and materials can be left for planarization (at operation 364).

In embodiments, operation 316 (as seen in FIG. 3B), and/or operations 346 through 364 (as seen in FIG. 3C) can be repeated so as to form more than one copper lines through one or more dielectric layers of an RDL. These one or more dielectric layers can be inorganic dielectric layers (e.g., including an inorganic dielectric such as silicon nitride or silicon dioxide). In embodiments, these inorganic buildup layers can be formed on the first layer stack 410. In embodiments, layer stack 440 can include Si₃N₄. In embodiments, operation 314, and/or operations 322 through 344 can be repeated any number of times as is feasible or appropriate.

At operation 318, a third layer stack of the exterior portion of the RDL of the packaging substrate can be formed on the second layer stack. Such a layer stack can be seen in FIGS. 4A-C as third layer stack 470, which can be formed above or onto the second layer stack 440.

In embodiments, the third portion of operation 318 can be formed by depositing a dielectric layer, and etching the dielectric layer. These suboperations of operation 318 and the formation of the third layer stack of the exterior layer will now be described in further detail with respect to both FIGS. 3C and 4A-C.

In embodiments, depositing the dielectric layer of operation 316 can include depositing a dielectric layer (e.g., layer 474) onto the second portion (e.g., onto the top-most layer of layer stack 440). This can be seen at operation 366 of FIG. 3E, as well as within FIGS. 4A-C.

In embodiments, etching the third dielectric layer of operation 316, can include depositing a photoresist pattern onto the dielectric layer, as seen at operation 368, performing an etching process to expose the conductive layer, as seen at operation 372, and removing the photoresist, as seen at operation 374. In embodiments, such an etching process of operation 372 can leave an opening (e.g., opening 480) so as to prepare for metal finishing. A metal finishing layer can be deposited onto the exterior-most layer of the RDL. In embodiments, an electroless nickel electroless palladium immersion gold (ENEPIG) deposition process can be used for finishing. ENEPIG deposition can be or include the deposition of a layer of nickel, followed by palladium, followed by a layer of gold.

In alternative embodiments, the third dielectric layer of operation 316 is not etched. The layer 474 may be applied and then planarized. This results in a layer of dielectric material remaining to cover the conductive material, such as is illustrated in the FIG. 4B. In some embodiments, the third dielectric layer of operation 318 (e.g., the layer 474) can be a thicker layer than would be applied if the conductive layer were to later be exposed, such as is illustrated in the FIG. 4C. In some embodiments, the opening 480 may be created to expose the conductive layer, and an organic dielectric layer disposed on the conductive layer.

In embodiments, various techniques for etching can produce different achievable ranges, or have different capabilities for minimum bump pitch. For instance, in embodiments, laser drilling can be capable of producing cavities and/or conductive pathways with a bump pitch that is reducible to a minimum of 130 μm, a solder mask opening that is reducible to a minimum of 80 μm, and/or separation that is reducible to a minimum of 50 μm. In embodiments, laser drilling can be performed through any of the dielectric materials previously discussed (e.g., ABF; e.g., SiO₂, Si₃N₄, etc.).

In embodiments, digital lithography can be capable of producing cavities and/or conductive pathways with a bump pitch that is reducible to a minimum of 35 μm, a pad size that is reducible to a minimum of 25 μm, and/or separation that is reducible to a minimum of 10 μm. In embodiments, digital lithography can be performed through any of the dielectric materials previously discussed (e.g., a photosensitive polyimide; e.g., ABF, SiO₂, Si₃N₄, etc.).

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, but on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within the range, unless otherwise indicated herein, and each separate value is incorporated into the specification as if it were individually recited herein. In at least one embodiment, the use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but subset and corresponding set can be equal.

Conjunctive language, such as phrases of the form “at least one of A, B, and C,” or “at least one of A, B and C,” unless specifically stated otherwise or otherwise clearly contradicted by context, is otherwise understood with the context as used in general to present that an item, term, etc., can be either A or B or C, or any nonempty subset of the set of A and B and C. For instance, in an illustrative example of a set having three members, conjunctive phrases “at least one of A, B, and C” and “at least one of A, B and C” refer to any of the following sets: {A}, {B}, {C}, {A, B}, {A, C}, {B, C}, {A, B, C}. Thus, such conjunctive language is not generally intended to imply that certain embodiments include at least one of A, at least one of B and at least one of C each to be present. In addition, unless otherwise noted or contradicted by context, the term “plurality” indicates a state of being plural (e.g., “a plurality of items” indicates multiple items). In at least one embodiment, the number of items in a plurality is at least two, but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in the form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. In at least one embodiment, a set of non-transitory computer-readable storage media comprises multiple non-transitory computer-readable storage media and one or more of individual non-transitory storage media of multiple non-transitory computer-readable storage media lack all of the code while multiple non-transitory computer-readable storage media collectively store all of the code. In at least one embodiment, executable instructions are executed such that different instructions are executed by different processors.

Accordingly, in at least one embodiment, computer systems are configured to implement one or more services that singly or collectively perform operations of processes described herein and such computer systems are configured with applicable hardware and/or software that enable the performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

In description and claims, terms “coupled” and “connected,” along with their derivatives, can be used. It should be understood that these terms may not be intended as synonyms for each other. Rather, in particular examples, “connected” or “coupled” can be used to indicate that two or more elements are in direct or indirect physical or electrical contact with each other. “Coupled” can also mean that two or more elements are not in direct contact with each other, but yet still co-operate or interact with each other.

Unless specifically stated otherwise, it can be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, the term “processor” can refer to any device or portion of a device that processes electronic data from registers and/or memory and transform that electronic data into other electronic data that can be stored in registers and/or memory. A “computing platform” can comprise one or more processors. As used herein, “software” processes can include, for example, software and/or hardware entities that perform work over time, such as tasks, threads, and intelligent agents. Also, each process can refer to multiple processes, for carrying out instructions in sequence or in parallel, continuously, or intermittently. In at least one embodiment, terms “system” and “method” are used herein interchangeably insofar as the system can embody one or more methods and methods can be considered a system.

In the present document, references can be made to obtaining, acquiring, receiving, or inputting analog or digital data into a subsystem, computer system, or computer-implemented machine. In at least one embodiment, the process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references can also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or inter-process communication mechanism.

Although descriptions herein set forth example embodiments of described techniques, other architectures can be used to implement described functionality, and are intended to be within the scope of this disclosure. Furthermore, although specific distributions of responsibilities can be defined above for purposes of description, various functions and responsibilities might be distributed and divided in different ways, depending on circumstances.

Furthermore, although the subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A packaging substrate, comprising:
a core;
a one or more first organic buildup layers on a first side of the core, the one or more first organic buildup layers comprising an organic dielectric material and at least one of first metallic traces, first metallic vias, or first metallic pads;
a one or more second organic buildup layers on a second side of the core that is opposite the first side, the one or more second organic buildup layers comprising the organic dielectric material and at least one of second metallic traces, second metallic vias, or second metallic pads; and
one or more first inorganic buildup layers disposed on the one or more first organic buildup layers, the one or more first inorganic buildup layers comprising an inorganic dielectric material and at least one of third metallic traces, third metallic vias, or third metallic pads.

2. The packaging substrate of claim 1, wherein the one or more first organic buildup layers comprise metallic portions that protrude from an exterior-most surface of the organic dielectric material of the one or more first organic buildup layers.

3. The packaging substrate of claim 1, wherein the one or more first organic buildup layers comprise metallic portions that are planar with an exterior-most surface of the organic dielectric material of the one or more first organic buildup layers.

4. The packaging substrate of claim 1, wherein a distance between centers of adjacent metallic pads of the first metallic pads is at most 100 micrometers (μm).

5. The packaging substrate of claim 1, wherein a cross section of the first metallic pads of the one or more first organic buildup layers is about 1-30 micrometers (μm).

6. The packaging substrate of claim 1, wherein the inorganic dielectric material comprises at least one of silicon dioxide (SiO₂) or silicon nitride (Si₃N₄).

7. The packaging substrate of claim 1, wherein the organic dielectric material comprises at least one of Ajinomoto buildup film (ABF) or polyimide.

8. The packaging substrate of claim 1, further comprising:
a one or more third organic buildup layers disposed on the one or more first inorganic build layers, the third one or more organic buildup layers comprising an organic dielectric material.

9. The packaging substrate of claim 1, wherein a distance between centers of adjacent metallic pads of the first metallic pads is about 5-50 micrometers (μm).

10. The packaging substrate of claim 1, wherein at least one of the one or more via structures is a blind via with a diameter at most 10 micrometers (μm), and wherein at least one of the one or more via structures is a through-assembly via with a diameter at most 30 μm.

11. The packaging substrate of claim 1, further comprising one or more second inorganic buildup layers disposed on the one or more second organic buildup layers, the one or more second inorganic buildup layers comprising the inorganic dielectric material and at least one of fourth metallic traces, fourth metallic vias, or fourth metallic pads.

12. A method comprising:
depositing a first exterior layer comprising a first inorganic dielectric material onto a first side of a packaging substrate comprising a core and one or more interior layers on the first side, the one or more interior layers comprising a first organic dielectric material and a plurality of conductive traces;
removing portions of the first exterior layer to form structures exposing portions of the plurality of conductive traces;
depositing conductive material within the structures of the first exterior layer to form at least one of a plurality of vias or a plurality of fine traces electrically connected to the plurality of conductive traces;
depositing a second exterior layer comprising a second inorganic dielectric material onto the first exterior layer;
removing at least a portion of the second exterior layer to form structures exposing portions of the plurality of vias; and
depositing conductive material within the structures of the second exterior layer to form a plurality of contact pads configured to electrically connect the packaging substrate to an integrated circuit.

13. The method of claim 12, wherein a distance between centers of adjacent contact pads of the plurality of contact pads is at most 20 micrometers (μm).

14. The method of claim 12, wherein a cross section of the plurality of contact pads is about 5-20 micrometers (μm).

15. The method of claim 12, wherein the first inorganic dielectric material comprises silicon dioxide (SiO₂) and wherein removing portions of the first exterior layer comprises employing at least one of photoresist application, photolithography, chemical etching, or plasma etching to the first exterior layer.

16. The method of claim 12, wherein the core is a silicon core.

17. The method of claim 12, wherein a distance between centers of adjacent contact pads of the plurality of contact pads is about 5-20 micrometers (μm).

18. A system, comprising:
a packaging substrate;
an integrated chip (IC) conductively connected to a first side of the packaging substrate; and
a printed circuit board (PCB) conductively connected to a second side of the packaging substrate, wherein the packaging substrate comprises:
a core;
a one or more first organic buildup layers on a first side of the core, the one or more first organic buildup layers comprising an organic dielectric material and at least one of first metallic traces, first metallic vias, or first metallic pads;
a one or more second organic buildup layers on a second side of the core that is opposite the first side, the one or more second organic buildup layers comprising the organic dielectric material and at least one of second metallic traces, second metallic vias, or second metallic pads; and
one or more first inorganic buildup layers disposed on the one or more first organic buildup layers, the one or more first inorganic buildup layers comprising an inorganic dielectric material and at least one of third metallic traces, third metallic vias, or third metallic pads.

19. The system of claim 18, wherein the one or more first organic buildup layers comprise metallic portions that are planar with an exterior-most surface of the organic dielectric material of the one or more first organic buildup layers.

20. The system of claim 18, further comprising one or more second inorganic buildup layers disposed on the one or more second organic buildup layers, the one or more second inorganic buildup layers comprising the inorganic dielectric material and at least one of fourth metallic traces, fourth metallic vias, or fourth metallic pads.
